(19) United States
(12) Patent Application Publication
(10) Pub. No.: US 2024/0105773 A1
(43) Pub. Date: Mar. 28, 2024

(54) SEMICONDUCTOR DEVICE

(71) Applicant: Samsung Electronics Co., Ltd., Suwon-si (KR)

(72) Inventors: Hae Jun YU, Suwon-si (KR); Kyung In CHOI, Suwon-si (KR); Soon Wook JUNG, Suwon-si (KR)

(21) Appl. No.: 18/332,784

(22) Filed: Jun. 12, 2023

(30) Foreign Application Priority Data
Sep. 28, 2022 (KR) 10-2022-0123049

(51) Int. Cl. H01L 29/06; H01L 29/08; H01L 29/417; H01L 29/423; H01L 29/775; H01L 29/786

(52) U.S. Cl. CPC H01L 29/0673; H01L 29/0847; H01L 29/41733; H01L 29/42392; H01L 29/775; H01L 29/78696

(57) ABSTRACT

There is provided a semiconductor device having improved performance and reliability. A semiconductor device comprises an active pattern extending in a first direction, a gate structure including a gate electrode, a gate spacer, and a gate capping pattern on the active pattern, the gate electrode extending in a second direction different from the first direction and the gate capping pattern including a lower gate capping pattern and an upper gate capping pattern; a source/drain pattern disposed on the active pattern; and a source/drain etch stop film disposed on an upper surface of the source/drain pattern and extending along a sidewall of the gate spacer. The lower gate capping pattern is disposed on an upper surface of the gate electrode and an upper surface of the gate spacer, and the source/drain etch stop film does not extend along a sidewall of the lower gate capping pattern.

### CROSS-REFERENCE TO RELATED APPLICATION

This application claims priority to Korean Patent Application No. 10-2022-0123049 filed on Sep. 28, 2022 in the Korean Intellectual Property Office, and all the benefits accruing therefrom under 35 U.S.C. 119, the entire disclosure of which is incorporated herein by reference.

### BACKGROUND

The present disclosure relates to a semiconductor device.

One of scaling schemes for increasing a density of a semiconductor device includes a multi-gate transistor in which a multi-channel active pattern (or a silicon body) in a shape of a fin or a nanowire is formed on a substrate, and a gate is formed on a surface of the multi-channel active pattern.

Because such a multi-gate transistor uses a three-dimensional channel, it is easy to scale the same. Further, current control capability of the multi-gate transistor may be improved without increasing a gate length of the multi-gate transistor. In addition, the multi-gate transistor may effectively suppress SCE (short channel effect) in which potential of a channel area is affected by drain voltage.

As a pitch size of a semiconductor device decreases, various research on reducing capacitance and securing electrical stability (e.g., isolation) between contacts in the semiconductor device has been conducted.

### SUMMARY

A purpose of the present disclosure is to provide a semiconductor device having improved performance and reliability.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

According to an aspect of the present disclosure, there is provided a semiconductor device comprising an active pattern extending in a first direction, a gate structure including a gate electrode, a gate spacer, and a gate capping pattern on the active pattern, the gate electrode extending in a second direction different from the first direction and the gate capping pattern including a lower gate capping pattern and an upper gate capping pattern on the lower gate capping pattern, a source/drain pattern disposed on the active pattern; and a source/drain etch stop film disposed on an upper surface of the source/drain pattern and extending along a sidewall of the gate spacer, wherein the lower gate capping pattern is disposed on an upper surface of the gate electrode and an upper surface of the gate spacer, and the source/drain etch stop film does not extend along a sidewall of the lower gate capping pattern. In some embodiments, the sidewall of the lower gate capping pattern may be free of the source/drain etch stop film.

According to another aspect of the present disclosure, there is provided a semiconductor device comprising an active pattern extended in a first direction, a gate structure including a gate electrode, a gate spacer, and a gate capping pattern on the active pattern, the gate electrode extending in a second direction different from the first direction, the gate capping pattern including a lower gate capping pattern and an upper gate capping pattern on the lower gate capping pattern, a source/drain pattern disposed on the active pattern, and a source/drain etch stop film disposed on an upper surface of the source/drain pattern and extending along a sidewall of the gate spacer, wherein the lower gate capping pattern is in contact with an upper surface of the gate electrode and an upper surface of the gate spacer, an upper surface of the lower gate capping pattern includes a first inclined surface and a second inclined surface connected to each other, and the first inclined surface of the upper surface of the lower gate capping pattern and the second inclined surface of the upper surface of the lower gate capping pattern are in contact with the upper gate capping pattern.

According to still another aspect of the present disclosure, there is provided an active pattern which includes a bottom pattern extending in a first direction, and a plurality of sheet patterns space apart from the bottom pattern in a second direction a gate structure including a gate electrode, a gate spacer, and a gate capping pattern on the active pattern, the gate electrode extending in a third direction, the gate capping pattern including a lower gate capping pattern and an upper gate capping pattern on the lower gate capping pattern, a source/drain pattern disposed on the active pattern, and a source/drain etch stop film disposed on an upper surface of the source/drain pattern and extending along a sidewall of the gate spacer, wherein the lower gate capping pattern is in contact with an upper surface of the gate electrode and an upper surface of the gate spacer, the upper gate capping pattern includes a first cavity (e.g., air gap) or a first seam, and the upper gate capping pattern may include an upper surface of the gate capping pattern. In some embodiments, the upper gate capping pattern may define the upper surface of the gate capping pattern.

### BRIEF DESCRIPTION OF THE DRAWINGS

The above and other aspects and features of the present disclosure will become more apparent by describing in detail example embodiments thereof with reference to the attached drawings, in which:

FIG. 1 is an example layout diagram of a semiconductor device according to some embodiments;

FIGS. 2 to 4 are example cross-sectional views taken along A-A, B-B, and C-C of FIG. 1, respectively, according to some embodiments;

FIG. 5 is an enlarged view of P portion of FIG. 2;

FIGS. 6 to 8 are example cross-sectional views of a semiconductor device according to some embodiments;

FIGS. 9 and 10 are example cross-sectional views of a semiconductor device according to some embodiments;

FIGS. 11 and 12 are example cross-sectional views of a semiconductor device according to some embodiments;

FIGS. 13 and 14 are example cross-sectional views of a semiconductor device according to some embodiments;

FIG. 15 is an example cross-sectional view of a semiconductor device according to some embodiments;

FIGS. 16 and 17 are example cross-sectional views of a semiconductor device according to some embodiments;

FIGS. 18 and 19 are example cross-sectional views of a semiconductor device according to some embodiments;

FIG. 20 is an example cross-sectional view of a semiconductor device according to some embodiments.

FIG. 21 is an example cross-sectional view of a semiconductor device according to some embodiments.

FIGS. 22 to 26 are diagrams illustrating a semiconductor device according to some embodiments;

FIGS. 27 and 28 are example layout diagrams of a semiconductor device according to some embodiments, respectively;

FIGS. 29 to 38 are example cross-sectional views of intermediate structures illustrating a semiconductor device manufacturing method according to some embodiments.

### DETAILED DESCRIPTIONS

For simplicity and clarity of illustration, elements in the drawings are not necessarily drawn to scale. The same reference numbers in different drawings represent the same or similar elements, and as such perform similar functionality. Further, descriptions and details of well-known steps and elements may be omitted for simplicity of the description. Furthermore, in the following detailed description, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described herein. Rather, it is intended to cover alternatives, modifications, and equivalents as may be included within the scope of the present disclosure as defined by the appended claims.

A shape, a size, a ratio, an angle, a number, etc. disclosed in the drawings for illustrating embodiments of the present disclosure are examples, and the present disclosure is not limited thereto.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify an entirety of list of elements and may not modify the individual elements of the list. When referring to “C to D”, this means C inclusive to D unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, two consecutive blocks may actually be executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated. The features of the various embodiments of the present disclosure may be partially or entirely combined with each other, and may be technically associated with each other or operate with each other. The embodiments may be implemented independently of each other and may be implemented together in an association relationship. Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

Hereinafter, example embodiments of the present disclosure will be described with reference to the drawings.

In the drawings of a semiconductor device according to some embodiments, a fin-shaped transistor (FinFET) including a channel area of a fin-shaped pattern, a transistor including a nanowire or a nanosheet, or a MBCFET™ (a Multi-Bridge Channel Field Effect Transistor) is shown by way of example. The present disclosure is not limited thereto. In some embodiments, a semiconductor device according to some embodiments may include a tunneling transistor (a tunneling FET), a three-dimensional (3D) transistor or a vertical transistor (a vertical FET). In some other embodiments, a semiconductor device according to some embodiments may include a planar transistor. In addition, the technical idea of the present disclosure may be applied to transistors (2D material based FETs) based on a 2D material and a heterostructure thereof.

Further, a semiconductor device according to some embodiments may include a bipolar junction transistor, a lateral double diffusion transistor (LDMOS), and the like.

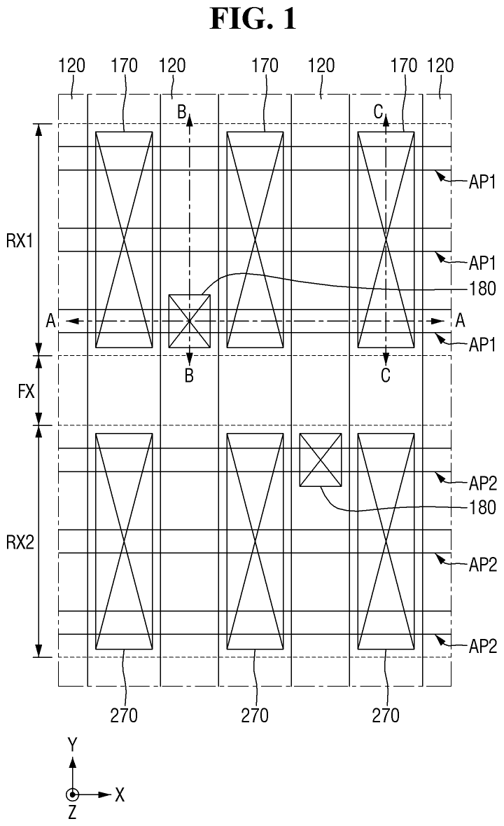

With reference to FIGS. 1 to 5, a description of a semiconductor device according to some embodiments will be made.

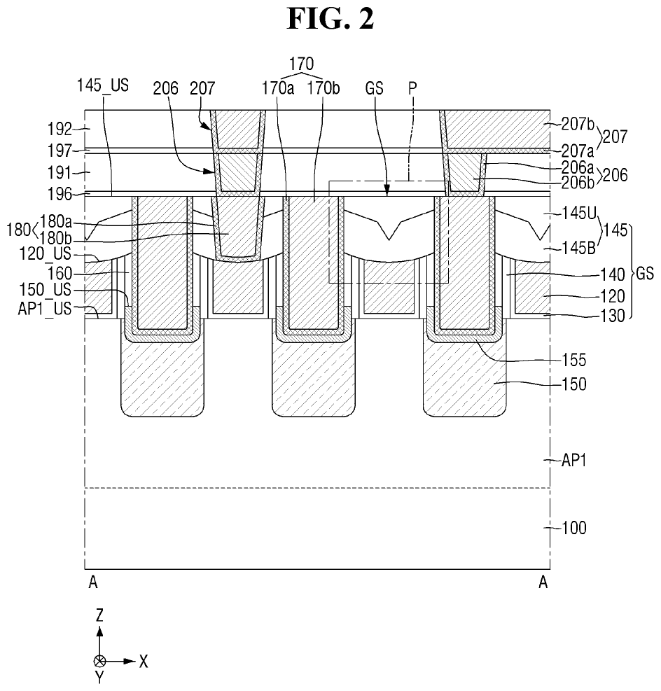

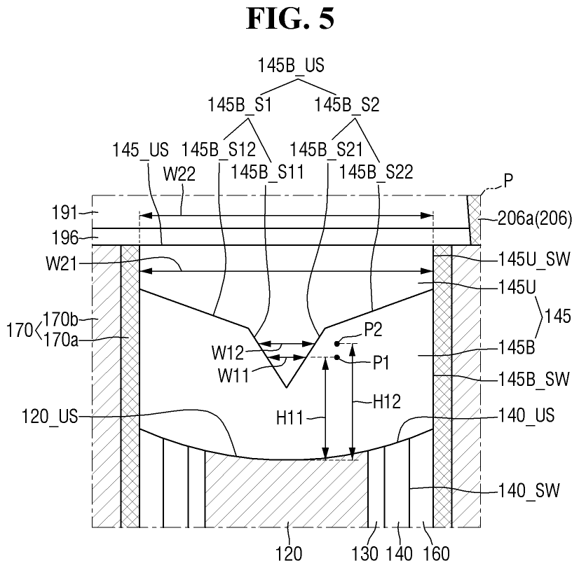

FIG. 1 is an example layout diagram of a semiconductor device according to some embodiments. FIGS. 2 to 4 are example cross-sectional views taken along A-A, B-B, and C-C of FIG. 1, respectively, according to some embodiments. FIG. 5 is an enlarged view of P portion of FIG. 2. For convenience of explanation, a via plug 206 and a wiring line 207 are not shown in FIG. 1.

For reference, it is illustrated in FIG. 2 that the via plug 206 connected to a first source/drain contact 170 and the via plug 206 connected to a gate contact 180 are adjacent to each other in a first direction X while being disposed on one first active pattern AP1. However, such an arrangement of the via plugs 206 is intended only for convenience of illustration. The present disclosure is not limited thereto.

Although not shown, a cross-sectional view taken in the first direction X along a second active pattern AP2 may be similar to FIG. 2 except for positions of the via plug 206 and the wiring line 207.

Referring to FIGS. 1 to 5, the semiconductor device according to some embodiments may include a substate 100, at least one first active pattern AP1, at least one second active pattern AP2, at least one gate structure GS, a source/drain etch stop film 160, a first source/drain contact 170, a second source/drain contact 270, and a gate contact 180.

The substrate 100 may include a first active area RX1, a second active area RX2, and a field area FX. The field area FX may be immediately adjacent to the first active area RX1 and the second active area RX2. The field area FX may be positioned between the first active area RX1 and the second active area RX2.

The first active area RX1 and the second active area RX2 are spaced apart from each other. The first active area RX1 and the second active area RX2 may be spaced from each other while the field area FX is disposed therebetween.

In other words, an element isolation film may be disposed around the first active area RX1 and the second active area RX2 that are spaced apart from each other. In this regard, a portion of the element isolation film between the first active area RX1 and the second active area RX2 may be the field area FX. For example, an area in which a channel area of a transistor which may be an example of the semiconductor device is formed may be an active area, while an area defining the channel area of the transistor formed in the active area may be the field area. Alternatively, the active area may be an area in which a fin-shaped pattern or a nanosheet used as the channel area of the transistor is formed, while the field area may be an area in which the fin-shaped pattern or the nanosheet used as the channel area is not formed.

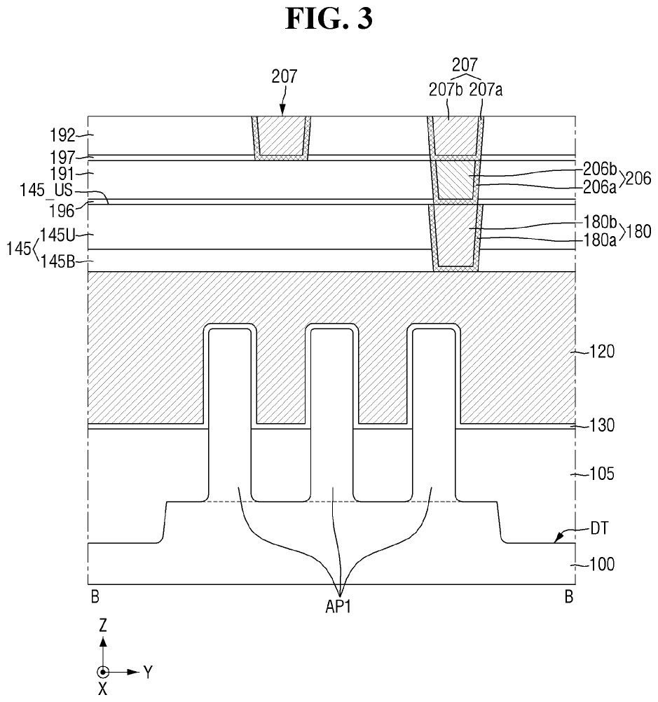

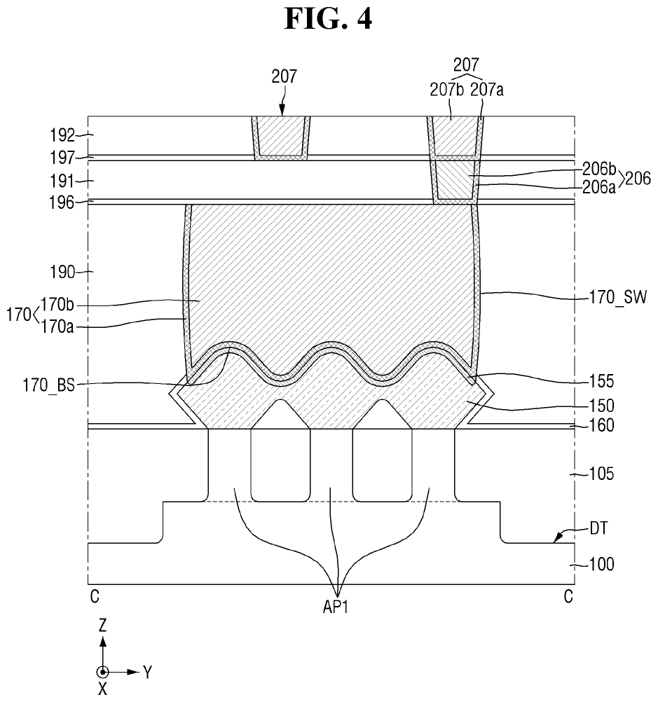

As shown in FIGS. 3 and 4, the field area FX may be defined by a deep trench DT. However, the present disclosure is not limited thereto. In addition, a person skilled in the art to which the present disclosure belongs would understand which portion is the field area and which portion is the active area.

In one example, one of the first active area RX1 and the second active area RX2 may be an area in which a PMOS is formed, and the other thereof may be an area in which a NMOS is formed. In another example, each of the first active area RX1 and the second active area RX2 may be an area in which a PMOS is formed. In still another example, each of the first active area RX1 and the second active area RX2 may be an area in which a NMOS is formed

The substrate 100 may be embodied as, for example, a silicon substrate or an SOI (silicon-on-insulator) substrate. In some embodiments, the substrate 100 may include, but not limited to, silicon-germanium, SGOI (silicon germanium on insulator), indium antimonide, a lead telluride compound, indium arsenide, indium phosphide, gallium arsenide, or gallium antimonide.

At least one first active pattern AP1 may be formed in the first active area RX1. The first active pattern AP1 may protrude from a portion of the substrate 100 in the first active area RX1. The first active pattern AP1 may extend in an elongate manner along the first direction X while being disposed on the substrate 100. Stated differently, the first active pattern AP1 may extend longitudinally in the first direction X. For example, the first active pattern AP1 may include a long side extending in the first direction X and a short side extending in the second direction Y. In this regard, the first direction X may intersect the second direction Y and a third direction Z. Further, the second direction Y may intersect the third direction Z. The third direction Z may be a thickness direction of the substrate 100.

At least one second active pattern AP2 may be formed in the second active area RX2. Description of the second active pattern AP2 may be substantially the same as the above description of the first active pattern AP1.

Each of the first active pattern AP1 and the second active pattern AP2 may be a multi-channel active pattern. In the semiconductor device according to some embodiments, each of the first active pattern AP1 and the second active pattern AP2 may be, for example, a pin-type pattern. Each of the first active pattern AP1 and the second active pattern AP2 may act as a channel area of a transistor. Although it is illustrated that each of the first active pattern AP1 and the second active pattern AP2 includes three active patterns, this is intended only for convenience of illustration. The present disclosure is not limited thereto. Each of the first active pattern AP1 and the second active pattern AP2 may be one, two or more than three.

Each of the first active pattern AP1 and the second active pattern AP2 may be a portion of the substrate 100, or may include an epitaxial layer grown from the substrate 100. Each of the first active pattern AP1 and the second active pattern AP2 may include, for example, silicon or germanium as an elemental semiconductor material. In some embodiments, each of the first active pattern AP1 and the second active pattern AP2 may include a compound semiconductor, for example, a group IV-IV compound semiconductor or a group III-V compound semiconductor.

The group IV-IV compound semiconductor may include, for example, a binary compound including two of carbon (C), silicon (Si), germanium (Ge), and tin (Sn), a ternary compound including three thereof, or a compound obtained by doping a group IV element thereto.

The group III-V compound semiconductor may include, for example, a binary compound obtained by combining one of aluminum (Al), gallium (Ga), and indium (In) as a group III element and one of phosphorus (P), arsenic (As), and antimony (Sb) as a group V element with each other, a ternary compound obtained by combining two of aluminum (Al), gallium (Ga), and indium (In) as a group III element and one of phosphorus (P), arsenic (As), and antimony (Sb) as a group V with each other, or a quaternary compound obtained by combining three of aluminum (Al), gallium (Ga), and indium (In) as a group III element and one of phosphorus (P), arsenic (As), and antimony (Sb) as a group V with each other.

In one example, the first active pattern AP1 and the second active pattern AP2 may include the same material. For example, each of the first active pattern AP1 and the second active pattern AP2 may be a silicon fin-shaped pattern. In some embodiments, for example, each of the first active pattern AP1 and the second active pattern AP2 may be a fin-shaped pattern including a silicon-germanium pattern. In some other embodiments, the first active pattern AP1 and the second active pattern AP2 may include different materials. For example, the first active pattern AP1 may be a silicon fin-shaped pattern, and the second active pattern AP2 may be a fin-shaped pattern including a silicon-germanium pattern.

The field insulating film 105 may be formed on the substrate 100. The field insulating film 105 may be formed along the first active area RX1, the second active area RX2, and the field area FX. The field insulating film 105 may fill the deep trench DT.

The field insulating film 105 may cover a sidewall of the first active pattern AP1 and a sidewall of the second active pattern AP2. Each of the first active pattern AP1 and the second active pattern AP2 may protrude upwardly beyond an upper surface of the field insulating film 105. The field insulating film 105 may include, for example, an oxide film, a nitride film, an oxynitride film, or a combination thereof.

At least one gate structure GS may be disposed on the substrate 100. For example, the at least one gate structure GS may be disposed on the field insulating film 105. The gate structure GS may extend in (e.g., may extend longitudinally in) the second direction Y. Adjacent gate structures GS may be spaced apart from each other in the first direction X.

The gate structure GS may be disposed on the first active pattern AP1 and the second active pattern AP2. The gate structure GS may intersect or traverse the first active pattern AP1 and the second active pattern AP2.

Although the gate structure GS is illustrated as being disposed along and on the first active area RX1 and the second active area RX2, this is intended only for convenience of illustration. The present disclosure is not limited thereto. That is, the gate structure GS may be divided into two portions via a gate separation structure disposed on the field insulating film 105, thereby the two portions are respectively disposed on the first active area RX1 and the second active area RX2.

The gate structure GS may include, for example, a gate electrode 120, a gate insulating film 130, a gate spacer 140, and a gate capping pattern 145.

The gate electrode 120 may be disposed on the first active pattern AP1 and the second active pattern AP2. The gate electrode 120 may intersect or traverse the first active pattern AP1 and the second active pattern AP2. The gate electrode 120 may surround or extend along each of a portion of the first active pattern AP1 and a portion of the second active pattern AP2 protruding upwardly beyond the upper surface of the field insulating film 105. The gate electrode 120 may include a long side extending in the second direction Y and a short side extending in the first direction X.

An upper surface 120_US of the gate electrode may be a concavely curved surface recessed toward an upper surface AP1_US of the first active pattern. However, the present disclosure is not limited thereto. That is, unlike what is illustrated, the upper surface 120_US of the gate electrode may be a flat surface.

The gate electrode 120 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) or combinations thereof. The present disclosure is not limited thereto.

The gate electrode 120 may include a conductive metal oxide, a conductive metal oxynitride, and the like or may include oxidized products of the aforementioned materials.

The gate electrode 120 may be disposed on both opposing sides of a source/drain pattern 150 to be described later. The gate structure GS may be disposed on both opposing sides in the first direction X of the source/drain pattern 150. In some embodiments, two gate electrodes 120 may be respectively disposed on opposing sides of a source/drain pattern 150.

In one example, each of gate electrodes 120 respectively disposed on opposing sides of the source/drain pattern 150 may be a normal gate electrode used as a gate of a transistor. In another example, one gate electrode 120 disposed on one side of the source/drain pattern 150 may be used as a gate of a transistor, while the other gate electrode 120 disposed on the other side of the source/drain pattern 150 may be a dummy gate electrode.

The gate spacer 140 may be disposed on a sidewall of the gate electrode 120. The gate spacer 140 may extend in (e.g., may extend longitudinally in) the second direction Y. The gate spacer 140 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or combinations thereof. However, the present disclosure is not limited thereto.

The gate insulating film 130 may extend along a sidewall and a bottom surface of the gate electrode 120. The gate insulating film 130 may be formed on the first active pattern AP1, the second active pattern AP2, and the field insulating film 105. The gate insulating film 130 may be formed between the gate electrode 120 and the gate spacer 140.

The gate insulating film 130 may be formed along a profile of a portion of the first active pattern AP1 protruding upwardly beyond the field insulating film 105 and along the upper surface of the field insulating film 105. Although not shown, the first gate insulating film 130 may be formed along a profile of a portion of the second active pattern AP2 protruding upwardly beyond the field insulating film 105.

The gate insulating film 130 may include silicon oxide, silicon oxynitride, silicon nitride, or a high dielectric constant material having a higher dielectric constant than that of silicon oxide. The high dielectric constant material may include at least one of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

Although it is illustrated that the gate insulating film 130 is embodied as a single film, this is intended only for convenience of illustration. The present disclosure is not limited thereto. The gate insulating film 130 may include a plurality of films. The gate insulating film 130 may include an interfacial film disposed between the first active pattern AP1 and the gate electrode 120 and between the second active pattern AP2 and the gate electrode 120, and may also include a high dielectric constant insulating film. For example, the interfacial film may be formed along a profile of a portion of the first active pattern AP1 protruding upwardly beyond the field insulating film 105, and a profile of a portion of the second active pattern AP2 protruding upwardly beyond the field insulating film 105.

The semiconductor device according to some embodiments may include an NC (negative capacitance) FET using a negative capacitor. For example, the gate insulating film 130 may include a ferroelectric material film having ferroelectric properties and a paraelectric material film having paraelectric properties.

The ferroelectric material film may have negative capacitance, and the paraelectric material film may have positive capacitance. For example, when two or more capacitors may be connected in series to each other, and capacitance of each of the capacitors has a positive value, a total capacitance is smaller than capacitance of each individual capacitor. On the contrary, when at least one of capacitances of two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. In this connection, in one example, hafnium zirconium oxide may refer to a material obtain by doping hafnium oxide with zirconium (Zr). In another example, hafnium zirconium oxide may refer to a compound of hafnium (Hf), zirconium (Zr), and oxygen (O).

The ferroelectric material film may further contain doped dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn). A type of the dopant contained in the ferroelectric material film may vary depending on a type of the ferroelectric material included in the ferroelectric material film.

When the ferroelectric material film includes hafnium oxide, the dopant contained in the ferroelectric material film may include, for example, at least one of gadolinium (Gd), silicon (Si), zirconium (Zr), aluminum (Al), and yttrium (Y).

When the dopant is aluminum (Al), the ferroelectric material film may include about 3 to about 8 at % (atomic %) of aluminum. In this connection, a ratio of the dopant may be the ratio aluminum to the sum of hafnium and aluminum.

When the dopant is silicon (Si), the ferroelectric material film may include about 2 to about 10 at % of silicon. When the dopant is yttrium (Y), the ferroelectric material film may include about 2 to about 10 at % yttrium. When the dopant is gadolinium (Gd), the ferroelectric material film may include about 1 to about 7 at % gadolinium. When the dopant is zirconium (Zr), the ferroelectric material film may include about 50 to about 80 at % zirconium.

The paraelectric material film may have paraelectric properties. The paraelectric material film may include, for example, at least one of silicon oxide and metal oxide having a high dielectric constant. The metal oxide contained in the paraelectric material film may include, for example, at least one of hafnium oxide, zirconium oxide and aluminum oxide. However, the present disclosure is not limited thereto.

The ferroelectric material film and the paraelectric material film may include the same material. The ferroelectric material film may have ferroelectric properties, but the paraelectric material film may not have the ferroelectric properties. For example, when each of the ferroelectric material film and the paraelectric material film includes hafnium oxide, a crystal structure of hafnium oxide contained in the ferroelectric material film is different from a crystal structure of hafnium oxide contained in the paraelectric material film.

The ferroelectric material film may have a thickness sized to exhibit ferroelectric properties. Although the thickness of the ferroelectric material film may be, for example, in a range of about 0.5 to about 10 nm, the present disclosure is not limited thereto. Because a critical thickness exhibiting the ferroelectric properties may vary based on a type of the ferroelectric material, the thickness of the ferroelectric material film may vary depending on the type of the ferroelectric material.

In one example, the gate insulating film 130 may include one ferroelectric material film. In another example, the gate insulating film 130 may include a plurality of ferroelectric material films spaced apart from each other. The gate insulating film 130 may have a stacked film structure in which a plurality of ferroelectric material films and a plurality of paraelectric material films are alternately stacked on top of each other.

A gate capping pattern 145 may be disposed on the upper surface 120_US of the gate electrode and on an upper surface 140_US of the gate spacer. In a cross-sectional view as shown in FIG. 2, the gate capping pattern 145 may cover an upper surface of the source/drain etch stop film 160. An upper surface 145_US of the gate capping pattern may be an upper surface of the gate structure GS. The gate capping pattern 145 may be an uppermost element of the gate structure GS, and thus the upper surface 145_US of the gate capping pattern 145 may define the upper surface of the gate structure GS.

The gate capping pattern 145 may include a lower gate capping pattern 145B and an upper gate capping pattern 145U.

The lower gate capping pattern 145B may be disposed on the gate electrode 120. The lower gate capping pattern 145B may be disposed on the upper surface 120_US of the gate electrode and the upper surface 140_US of the gate spacer.

In the cross-sectional view as shown in FIG. 2, the lower gate capping pattern 145B may cover an entirety of the upper surface 120_US of the gate electrode and an entirety of the upper surface 140_US of the gate spacer. The lower gate capping pattern 145B may contact the upper surface 120_US of the gate electrode and the upper surface 140_US of the gate spacer.

The lower gate capping pattern 145B includes an upper surface 145B_US facing the upper gate capping pattern 145U. The upper surface 145B_US of the lower gate capping pattern may include a first inclined surface 145B_S1 and a second inclined surface 145B_S2. The first inclined surface 145B_S1 as a portion of the upper surface of the lower gate capping pattern 145B is connected to the second inclined surface 145B_S2 as a portion of the upper surface of the lower gate capping pattern. In some embodiments, the first inclined surface 145B_S1 may be directly connected to the second inclined surface 145B_S2, as illustrated in FIG. 5.

A distance between the first inclined surface 145B_S1 of the upper surface of the lower gate capping pattern and the second inclined surface 145B_S2 of the upper surface of the lower gate capping pattern increases as each of the first inclined surface 145B_S1 and the second inclined surface 145B_S2 extends away from the upper surface 120_US of the gate electrode.

The lower gate capping pattern 145B may include a first point P1 and a second point P2. A distance W11 between the first inclined surface 145B_S1 and the second inclined surface 145B_S2 at the first point P1 is smaller than a distance W12 between the first inclined surface 145B_S1 and the second inclined surface 145B_S2 at the second point P2. A height H11 from the upper surface 120_US of the gate electrode to the first point P1 is smaller than a height H12 from the upper surface 120_US of the gate electrode to the second point P2. In some embodiments, the first inclined surface 145B_S1 and the second inclined surface 145B_S2 may diverge in a direction (e.g., a direction along the third direction Z) away from the upper surface 120_US of the gate electrode, as illustrated in FIG. 5. Accordingly, a distance (e.g., a distance in the first direction X) between the first inclined surface 145B_S1 and the second inclined surface 145B_S2 may increase as a distance (e.g., a distance in the third direction Z) from the upper surface 120_US of the gate electrode increases.

Each of the first inclined surface 145B_S1 of the upper surface of the lower gate capping pattern and the second inclined surface 145B_S2 of the upper surface of the lower gate capping pattern may include at least one sub-inclined surface. For example, the first inclined surface 145B_S1 of the upper surface of the lower gate capping pattern may include a first lower inclined surface 145B_S11 and a first upper inclined surface 145B_S12 connected to each other. The second inclined surface 145B_S2 of the upper surface of the lower gate capping pattern may include a second lower inclined surface 145B_S21 and a second upper inclined surface 145B_S22 connected to each other.

It is illustrated that each of the first inclined surface 145B_S1 and the second inclined surface 145B_S2 includes two sub-inclined surfaces. However, the present disclosure is not limited thereto. The number of sub-inclined surfaces included in the first inclined surface 145B_S1 may be the same as the number of sub-inclined surfaces included in the second inclined surface 145B_S2.

The first lower inclined surface 145B_S11 of the upper surface of the lower gate capping pattern is connected to (e.g., directly connected to) the second lower inclined surface 145B_S21 of the upper surface of the lower gate capping pattern. A slope of the first lower inclined surface 145B_S11 is different from slope of the first upper inclined surface 145B_S12. A slope of the second lower inclined surface 145B_S21 is different from that of the second upper inclined surface 145B_S22.

In the cross-sectional view, each of the first lower inclined surface 145B_S11, the first upper inclined surface 145B_S12, the second lower inclined surface 145B_S21, and the second upper inclined surface 145B_S22 may be flat. Unlike what is illustrated, the first upper inclined surface 145B_S12 may be a concavely curved surface or a convexly curved surface in the cross-sectional view. Accordingly, it will be understood that the first lower inclined surface 145B_S11, the first upper inclined surface 145B_S12, the second lower inclined surface 145B_S21, and the second upper inclined surface 145B_S22 in FIG. 5 are illustrated as examples.

The upper gate capping pattern 145U may be disposed on the lower gate capping pattern 145B. The lower gate capping pattern 145B may be disposed between the gate electrode 120 and the upper gate capping pattern 145U. The upper gate capping pattern 145U includes the upper surface 145_US of the gate capping pattern.

The upper gate capping pattern 145U may contact the upper surface 145B_US of the lower gate capping pattern. For example, the upper gate capping pattern 145U may contact the first inclined surface 145B_S1 of the upper surface of the lower gate capping pattern and the second inclined surface 145B_S2 of the upper surface of the lower gate capping pattern.

In the portion contacting with the top surface 145B_US of the lower gate capping pattern, a width in the first direction X of a portion of the upper gate capping pattern 145U increases as the portion extends away from the upper surface 120_US of the gate electrode.

For example, a width W22 in the first direction X of the upper gate capping pattern 145U may be equal to a width W21 in the first direction X of the lower gate capping pattern 145B. For example, the width W21 of the lower gate capping pattern 145B may be a width in the first direction X of the upper surface 145B_US of the lower gate capping pattern. The width W22 of the upper gate capping pattern 145U may be a width of a boundary or an interface between the upper gate capping pattern 145U and the lower gate capping pattern 145B. The width W22 in the first direction X of the upper gate capping pattern 145U may be a widest width of the upper gate capping pattern 145U in the first direction X.

The width W21 in the first direction X of the lower gate capping pattern 145B is larger than a width in the first direction X of a combination of the gate electrode 120, the gate insulating film 130 and the gate spacer 140.

Each of the lower gate capping pattern 145B and the upper gate capping pattern 145U may include, for example, one of silicon nitride (SiN), silicon oxynitride (SiON), silicon carbonitride (SiCN), silicon oxycarbonitride (SiOCN), silicon oxycarbide (SiOC), silicon carbide (SiC) or silicon boron nitride (SiBN). However, the present disclosure is not limited thereto. In some embodiments, the lower gate capping pattern 145B and the upper gate capping pattern 145U may include different materials.

The source/drain pattern 150 may be positioned on the substrate 100. The source/drain pattern 150 may be formed on the first active pattern AP1. The source/drain pattern 150 is connected to the first active pattern AP1.

The source/drain pattern 150 may be disposed on or adjacent a side surface of the gate structure GS. The source/drain pattern 150 may be disposed between the gate structures GS.

For example, source/drain patterns 150 may be disposed on opposing sides of the gate structure GS. Unlike what is illustrated, the source/drain pattern 150 may be disposed on one side of the gate structure GS and may not be disposed on the other side of the gate structure GS.

A height of the upper surface 150_US of the source/drain pattern may be higher than that of the upper surface AP1_US of the first active pattern. In the cross-sectional view as shown in FIG. 2, a height from a bottom of the first source/drain pattern 150 to the upper surface 150_US of the first source/drain pattern may be greater than a height from the bottom of the first source/drain pattern 150 to the upper surface AP1_US of the first active pattern.

The source/drain pattern 150 may include an epitaxial pattern. The source/drain pattern 150 may include a semiconductor material. The source/drain pattern 150 may be included in a source/drain of a transistor using the first active pattern AP1 as a channel area thereof.

The source/drain pattern 150 may be connected to a channel area of the first active pattern AP1 used as a channel. Although it is illustrated that the source/drain pattern 150 is embodied as a structure in which three epitaxial patterns respectively formed on the three first active patterns AP1 are merged with each other, this is intended only for convenience of explanation. However, the present disclosure is not limited thereto. That is, the epitaxial patterns respectively formed on the first active patterns AP1 may be spaced from each other.

In one example, in a space between the field insulating film 105 and the merged source/drain pattern 150, a cavity (e.g., an air gap) may be defined. In another example, the space between the field insulating film 105 and the merged source/drain pattern 150 may be filled with an insulating material. As used herein, “cavity” may be a gap filled with air (e.g., an air gap), a gap filled with an inert gas (e.g., an inert gas gap), a gap defining a vacuum (e.g., a vacuum gap), etc.

Although not shown, the source/drain pattern as aforementioned may be disposed on the second active pattern AP2 between the gate structures GS.

The source/drain etch stop film 160 may extend along the upper surface of the field insulating film 105, a sidewall 140SW of the gate spacer, and a profile of the source/drain pattern 150. The source/drain etch stop film 160 may be disposed on an upper surface 150_SW of the source/drain pattern 150 and a sidewall of the source/drain pattern 150.

An upper surface of the source/drain etch stop film 160 may be covered with the gate capping pattern 145. The source/drain etch stop film 160 does not extend to the upper surface 145_US of the gate capping pattern. Accordingly, the upper surface 145_US of the gate capping pattern may be free of the source/drain etch stop film 160.

The source/drain etch stop film 160 does not extend along a sidewall 145U_SW of the upper gate capping pattern. The source/drain etch stop film 160 does not contact the sidewall 145U_SW of the upper gate capping pattern. Accordingly, the sidewall 145U_SW of the upper gate capping pattern may be free of the source/drain etch stop film 160.

The source/drain etch stop film 160 does not extend along a sidewall 145B_SW of the lower gate capping pattern. The source/drain etch stop film 160 may not come into contact with the sidewall 145B_SW of the lower gate capping pattern. Accordingly, the sidewall 145B_SW of the lower gate capping pattern may be free of the source/drain etch stop film 160.

The source/drain etch stop film 160 may include a material having an etch selectivity with respect to a material of a first interlayer insulating film 190 to be described later. The source/drain etch stop film 160 may include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), or combinations thereof.

The first interlayer insulating film 190 is disposed on the source/drain etch stop film 160. The first interlayer insulating film 190 may be formed on the field insulating film 105. The first interlayer insulating film 190 may be disposed on the source/drain pattern 150. The first interlayer insulating film 190 may not cover the upper surface 145_US of the gate capping pattern. For example, an upper surface of the first interlayer insulating film 190 may be coplanar with the upper surface 145_US of the gate capping pattern.

The first interlayer insulating film 190 may include, for example, at least one of silicon oxide, silicon nitride, silicon oxynitride, and a low-k material. The low-k material may include, for example, fluorinated tetraethylorthosilicate (FTEOS), hydrogen silsesquioxane (HSQ), bi sbenzocyclobutene (BCB), tetramethylorthosilicate (TMOS), octamethyleyclotetrasiloxane (OMCTS), hexamethyldisiloxane (HMDS), trim ethyl silyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo silicate glass), SiLK, amorphous fluorinated carbon, silica aerogels, silica xerogels, mesoporous silica, or combinations thereof. However, the present disclosure is not limited thereto.

The first source/drain contact 170 may be disposed on the first active area RX1. The second source/drain contact 270 may be disposed on the second active area RX2. The first source/drain contact 170 may be connected to the source/drain pattern 150 formed in the first active area RX1. Although not shown, the second source/drain contact 270 may be connected to the source/drain pattern formed in the second active area RX2.

Unlike what is illustrated, a portion of the first source/drain contact 170 may be directly connected to a portion of the second source/drain contact 270. That is, in the semiconductor device according to some embodiments, at least one source/drain contact may be disposed along the first active area RX1 and the second active area RX2.

Since descriptions regarding the second source/drain contact 270 are substantially the same as the descriptions regarding the first source/drain contact 170, following descriptions are set forth based on the first source/drain contact 170 on the first active pattern AP1.

The gate contact 180 may be disposed in the gate capping pattern 145 and may be connected to the gate electrode 120 included in the gate structure GS.

The gate contact 180 may be disposed so as to overlap the gate structure GS. In the semiconductor device according to some embodiments, at least a portion of the gate contact 180 may be disposed so as to overlap at least one of the first active area RX1 and the second active area RX2.

For example, in a plan view, the gate contact 180 may entirely overlap the first active area RX1 or the second active area RX2.

The first source/drain contact 170 may extend through the source/drain etch stop film 160 so as to be connected to the source/drain pattern 150. The first source/drain contact 170 may be disposed on the source/drain pattern 150.

In FIGS. 2 and 5, the first source/drain contact 170 may cover an entirety of the sidewall 145U_SW of the upper gate capping pattern and an entirety of the sidewall 145B_SW of the lower gate capping pattern. For example, the first source/drain contact 170 may contact the sidewall 145U_SW of the upper gate capping pattern and the sidewall 145B_SW of the lower gate capping pattern. The first source/drain contact 170 may contact the source/drain etch stop film 160.

The first source/drain contact 170 may be disposed in the first interlayer insulating film 190. In FIG. 4, a sidewall 170_SW of the first source/drain contact may have a convex shape. For example, the sidewall 170_SW of the first source/drain contact may have a convexly curved surface in a cross-sectional view.

A contact silicide film 155 may be disposed between the first source/drain contact 170 and the source/drain pattern 150. The contact silicide film 155 is illustrated as being formed along a profile of an interface between the source/drain pattern 150 and the first source/drain contact 170. However, the present disclosure is not limited thereto. The contact silicide film 155 may include, for example, a metal silicide material.

In FIGS. 2 and 5, the contact silicide film 155 may contact a sidewall 140SW of the gate spacer. In this case, the upper surface 150_US of the source/drain pattern may be included in the contact silicide film 155. Unlike what is illustrated, the contact silicide film 155 may not come into contact with the sidewall 140SW of the gate spacer.

The first interlayer insulating film 190 does not cover an upper surface of the first source/drain contact 170. In one example, the upper surface of the first source/drain contact 170 may not protrude upwardly beyond the upper surface 145_US of the gate capping pattern. The upper surface of the first source/drain contact 170 may be coplanar with the upper surface 145_US of the gate capping pattern. Unlike what is illustrated, in another example, the upper surface of the first source/drain contact 170 may protrude upwardly beyond the upper surface 145_US of the gate capping pattern.

The first source/drain contact 170 may include a source/drain barrier film 170a and a source/drain filling film 170b on the source/drain barrier film 170a. The source/drain barrier film 170a may extend along a sidewall and a bottom surface of the source/drain filling film 170b.

A bottom surface 170_BS of the source/drain contact is illustrated as having a wavy shape. However, the present disclosure is not limited thereto. Unlike what is illustrated, in another example, the bottom surface 170_BS of the source/drain contact may have a flat shape.

Based on the upper surface AP1_US of the first active pattern, it is illustrated that the upper surface of the source/drain barrier film 170a is shown to be positioned at substantially the same height as the upper surface of the source/drain filling film 170b. However, the present disclosure is not limited thereto.

Unlike what is illustrated, based on the upper surface AP1_US of the first active pattern, the height of the upper surface of the source/drain barrier film 170a may be smaller than the height of the upper surface of the source/drain filling film 170b.

The source/drain barrier film 170a may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Jr), rhodium (Rh) and a two-dimensional (2D) material. In the semiconductor device according to some embodiments, the two-dimensional material may be a metallic material and/or a semiconductor material. The two-dimensional material may include two-dimensional allotrope or two-dimensional compound. For example, the two-dimensional material may include, but is not limited to, at least one of graphene, molybdenum disulfide (MoS₂), molybdenum diselenide (MoSe₂), tungsten diselenide (WSe₂), and tungsten disulfide (WS₂). That is, the above-described two-dimensional materials are only listed as examples. The two-dimensional material that may be included in the semiconductor device of the present disclosure is not limited to the above-described materials.

The source/drain filling film 170b may include, for example, at least one of aluminum (Al), tungsten (W), cobalt (Co), ruthenium (Ru), silver (Ag), gold (Au), manganese (Mn), or molybdenum (Mo).

The first source/drain contact 170 is illustrated as including a plurality of conductive films. However, the present disclosure is not limited thereto. Unlike what is illustrated, in another example, the first source/drain contact 170 may be embodied as a single film.

The gate contact 180 may be disposed on the gate electrode 120. The gate contact 180 may extend through the gate capping pattern 145 so as to be connected to the gate electrode 120.

In one example, an upper surface of the gate contact 180 may be coplanar with the upper surface 145_US of the gate capping pattern. Unlike what is illustrated, in another example, the upper surface of the gate contact 180 may protrude upwardly beyond the upper surface 145_US of the gate capping pattern.

The gate contact 180 may include a gate barrier film 180a and a gate filling film 180b on the gate barrier film 180a. A description directed to a material of each of the gate barrier film 180a and the gate filling film 180b may be the same as the description directed to the material of each of the source/drain barrier film 170a and the source/drain filling film 170b.

A first etch stop film 196 may be disposed on the first interlayer insulating film 190, the gate structure GS, the source/drain contact 170, and the gate contact 180. A second interlayer insulating film 191 is disposed on the first etch stop film 196.

The first etch stop film 196 may be disposed on the first interlayer insulating film 190, the gate structure GS, the source/drain contact 170, and the gate contact 180. The second interlayer insulating film 191 is disposed on the first etch stop film 196.

The first etch stop film 196 may include a material having an etch selectivity with respect to a material of the second interlayer insulating film 191. The first etch stop film 196 may include, for example, at least one of silicon nitride (SiN), silicon oxynitride (SiON), silicon oxycarbonitride (SiOCN), silicon boron nitride (SiBN), silicon oxyboronitride (SiOBN), silicon oxycarbide (SiOC), aluminum oxide (AlO), aluminum nitride (AlN), aluminum oxycarbonitride (AlOC) or combinations thereof. The first etch stop film 196 is illustrated as being embodied as a single film. However, the present disclosure is not limited thereto. Unlike what is illustrated, the first etch stop film 196 may not be formed (e.g., may be omitted). The second interlayer insulating film 191 may include, for example, at least one of silicon oxide, silicon nitride, silicon carbonitride, silicon oxynitride, and a low-k material.

The via plug 206 may be disposed in the second interlayer insulating film 191. The via plug 206 may extend through the first etch stop film 196 so as to be directly connected to the first source/drain contact 170 and the gate contact 180.

The via plug 206 may include a via barrier film 206a and a via filling film 206b. The via barrier film 206a may extend along a sidewall and a bottom surface of the via filling film 206b. The via barrier film 206a may include, for example, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Jr), rhodium (Rh) and a two-dimensional (2D) material. The via filling film 206b may include, for example, at least one of aluminum (Al), tungsten (W), cobalt (Co), ruthenium (Ru), silver (Ag), gold (Au), manganese (Mn), or molybdenum (Mo).

A second etch stop film 197 may be disposed between the second interlayer insulating film 191 and a third interlayer insulating film 192. The second etch stop film 197 may extend along an upper surface of the second interlayer insulating film 191.

The second etch stop film 197 may include a material having an etch selectivity with respect to a material of the third interlayer insulating film 192. A description directed to a material of the second etch stop film 197 may be the same as the description directed to the material of the first etch stop film 196. The second etch stop film 197 is illustrated as being embodied as a single film. However, the present disclosure is not limited thereto. Unlike what is illustrated, the upper etch stop film 196 may not be formed (e.g., may be omitted). The third interlayer insulating film 192 may include, for example, at least one of silicon oxide, silicon nitride, silicon carbonitride, silicon oxynitride, and a low-k material.

The wiring line 207 may be disposed in the third interlayer insulating film 192. The wiring line 207 is connected to the via plug 206. The wiring line 207 may contact the via plug 206.

The wiring line 207 may include a wiring barrier film 207a and a wiring filling film 207b. The wiring barrier film 207a may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Jr), rhodium (Rh) and a two-dimensional (2D) material. The wiring filling film 207b may include, for example, at least one of aluminum (Al), copper (Cu), tungsten (W), cobalt (Co), ruthenium (Ru), silver (Ag), gold (Au), manganese (Mn), or molybdenum (Mo).

Unlike what is illustrated, the wiring barrier film 207a may not be disposed between the via filling film 206b and the wiring filling film 207b. Although not shown, a first connection contact connecting the via plug 206 and the first source/drain contact 170 to each other may be further disposed between the via plug 206 and the first source/drain contact 170. Further, a second connection contact connecting the via plug 206 and the gate contact 180 to each other may be further disposed between the via plug 206 and the gate contact 180.

Unlike what is illustrated, the via plug 206 may not include the via barrier film. The via plug 206 may have a single conductive layer structure.

The via plug 206 connected to the first source/drain contact 170 may be a source/drain via plug. The via plug 206 connected to the gate contact 180 may be a gate via plug. Unlike what is illustrated, at least one of the source/drain via plug and the gate via plug may have a single conductive layer structure.

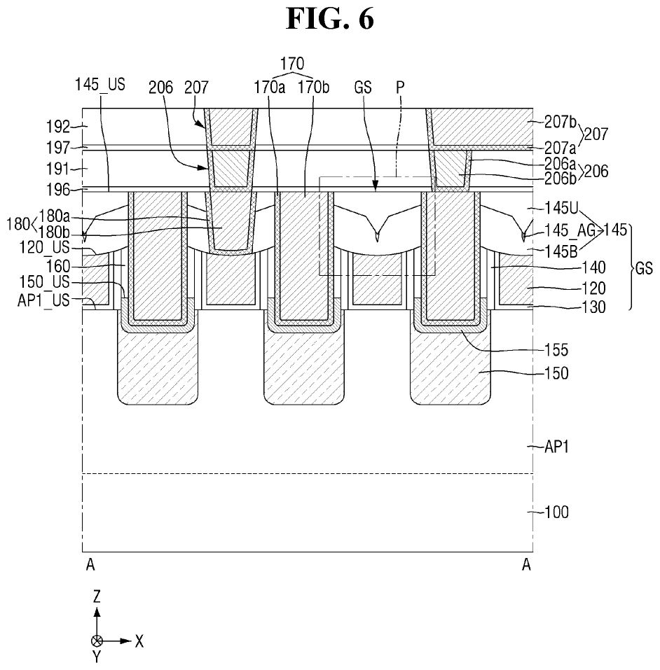

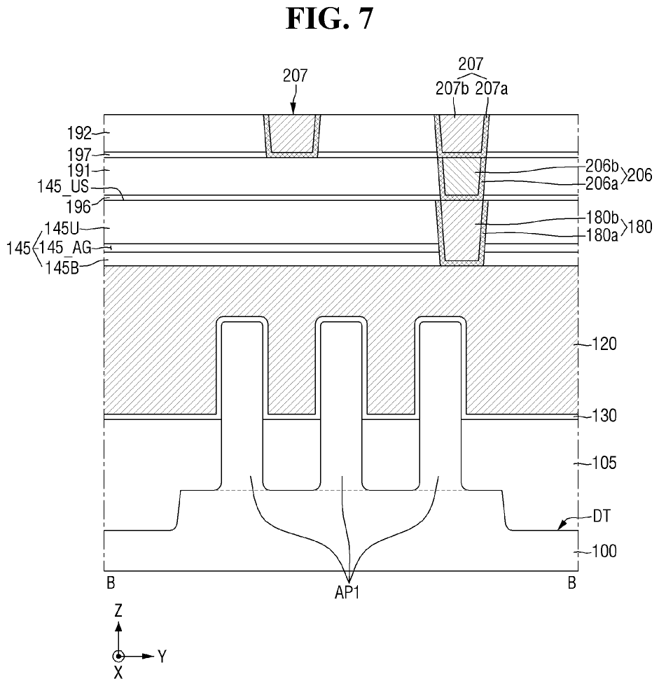

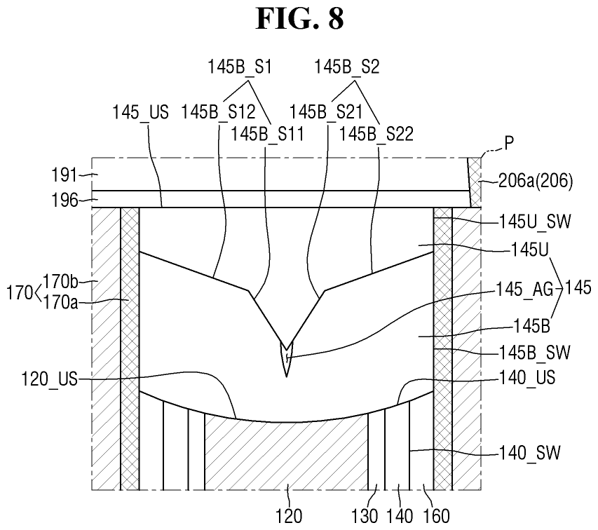

FIGS. 6 to 8 are example cross-sectional views of a semiconductor device according to some embodiments. For convenience of description, following descriptions mainly describe differences thereof from those as set forth with reference to FIGS. 1 to 5. For reference, FIG. 8 is an enlarged view of a P portion of FIG. 6.

Referring to FIGS. 6 to 8, in the semiconductor device according to some embodiments, the gate capping pattern 145 may further include a first inserted space pattern 145_AG disposed between the lower gate capping pattern 145B and the upper gate capping pattern 145U.

The first inserted space pattern 145_AG is disposed between the upper surface 145B_US of the lower gate capping pattern and a bottom surface of the upper gate capping pattern 145U. The first inserted space pattern 145_AG may extend in (e.g., may extend longitudinally in) the second direction Y. The gate contact 180 may extend through the first inserted space pattern 145_AG to the gate electrode 120.

In one example, the first inserted space pattern 145_AG may be a cavity (e.g., an air gap). In another example, the first inserted space pattern 145_AG may be a seam pattern or a seam.

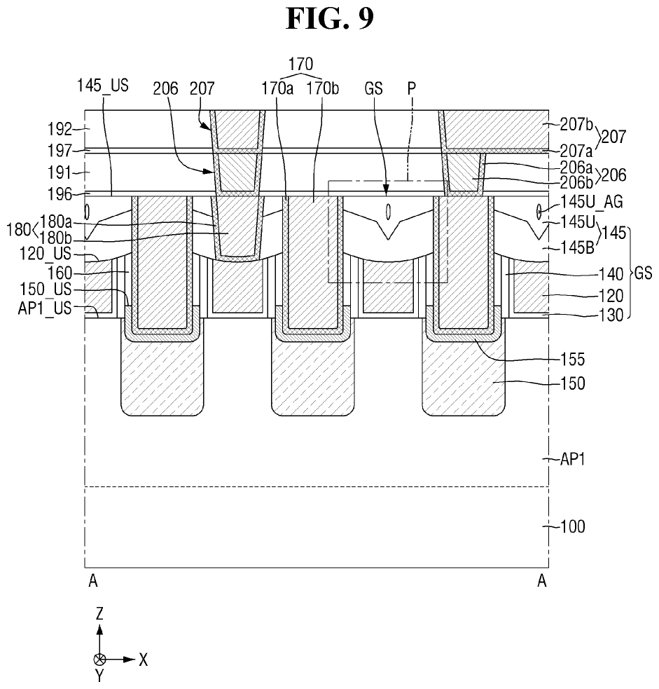

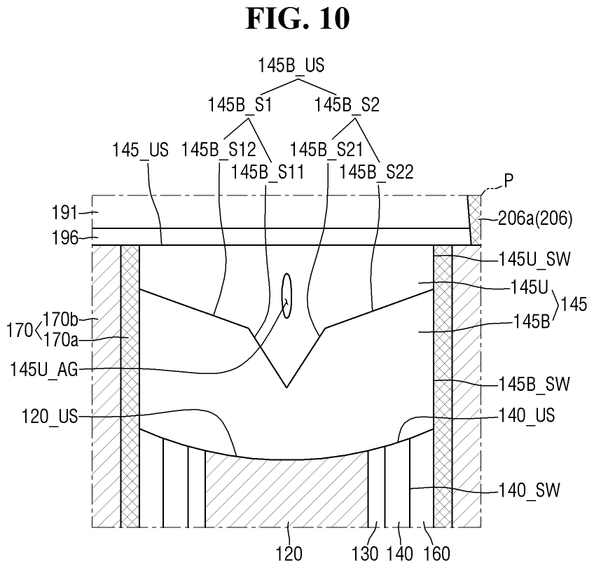

FIGS. 9 and 10 are example cross-sectional views of a semiconductor device according to some embodiments. For convenience of description, following descriptions mainly describe differences thereof from those as set forth with reference to FIGS. 1 to 5. For reference, FIG. 10 is an enlarged view of a P portion of FIG. 9.

Referring to FIGS. 9 and 10, in the semiconductor device according to some embodiments, the upper gate capping pattern 145U may include a second inserted space pattern 145U_AG.

The second inserted space pattern 145U_AG may be spaced apart from the lower gate capping pattern 145B in the third direction Z. Although not shown, the gate contact 180 may extend through the second inserted space pattern 145U_AG to the gate electrode 120.

In one example, the second inserted space pattern 145U_AG may be a cavity (e.g., an air gap). In another example, the second inserted space pattern 145U_AG may be a seam pattern or a seam.

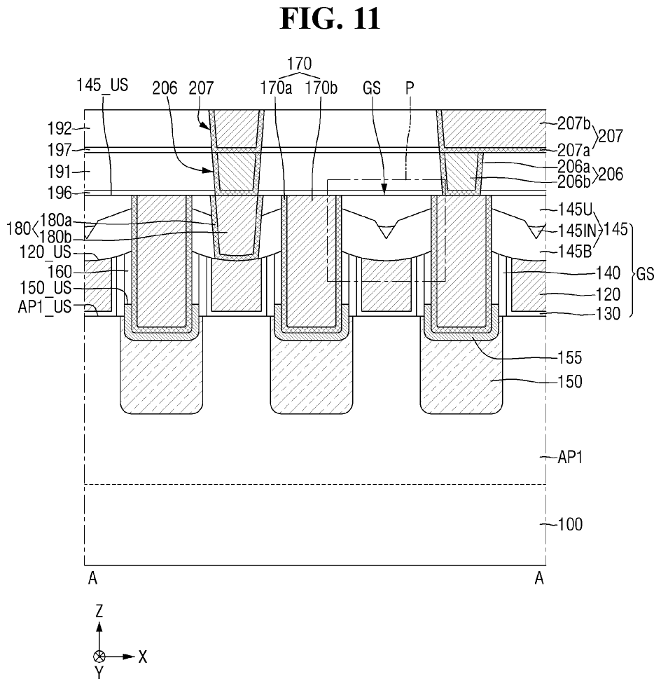

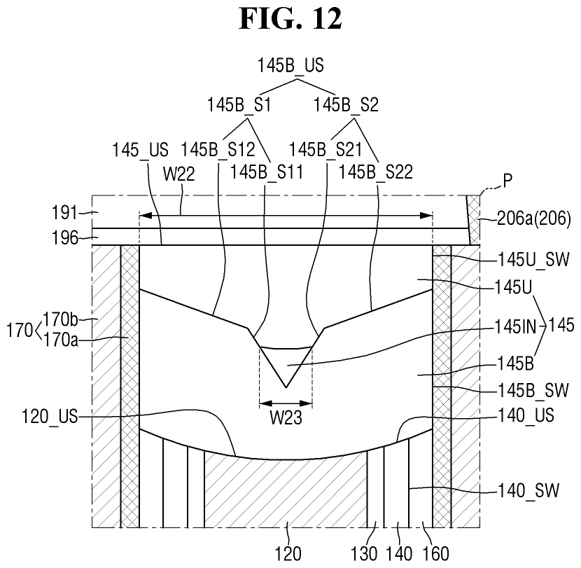

FIGS. 11 and 12 are example cross-sectional views of a semiconductor device according to some embodiments. For convenience of description, following descriptions mainly describe differences thereof from those as set forth with reference to FIGS. 1 to 5. For reference, FIG. 12 is an enlarged view of a P portion of FIG. 11.

Referring to FIGS. 11 and 12, in the semiconductor device according to some embodiments, the gate capping pattern 145 may further include an inserted gate capping pattern 145IN disposed between the lower gate capping pattern 145B and the upper gate capping pattern 145U.

The inserted gate capping pattern 145IN is disposed between the upper surface 145B_US of the lower gate capping pattern and the bottom surface of the upper gate capping pattern 145U. The inserted gate capping pattern 145IN may cover a portion of the first inclined surface 145B_S1 and a portion of the second inclined surface 145B_S2. The inserted gate capping pattern 145IN may be in contact with the portion of the first inclined surface 145B_S1 and the portion of the second inclined surface 145B_S2.

A width W23 in the first direction X of the inserted gate capping pattern 145IN is smaller than the width W21 in the first direction X of the lower gate capping pattern 145B. The width W23 in the first direction X of the inserted gate capping pattern 145IN is smaller than the width W22 in the first direction X of the upper gate capping pattern 145U. The width W23 in the first direction X of the inserted gate capping pattern 145IN may be a widest width of the inserted gate capping pattern 145IN in the first direction X.

Although not shown, the inserted gate capping pattern 145IN may extend in an elongate manner in the second direction Y. Stated differently, the inserted gate capping pattern 145IN may extend longitudinally in the second direction Y. The gate contact 180 may extend through the inserted gate capping pattern 145IN to the gate electrode 120.

The inserted gate capping pattern 145IN may include, for example, one of silicon nitride (SiN), silicon oxynitride (SiON), silicon oxide (SiO₂), silicon oxycarbonitride (SiOCN), silicon boron nitride (SiBN), silicon oxyboron nitride (SiOBN), or silicon oxycarbide (SiOC). However, the present disclosure is not limited thereto.

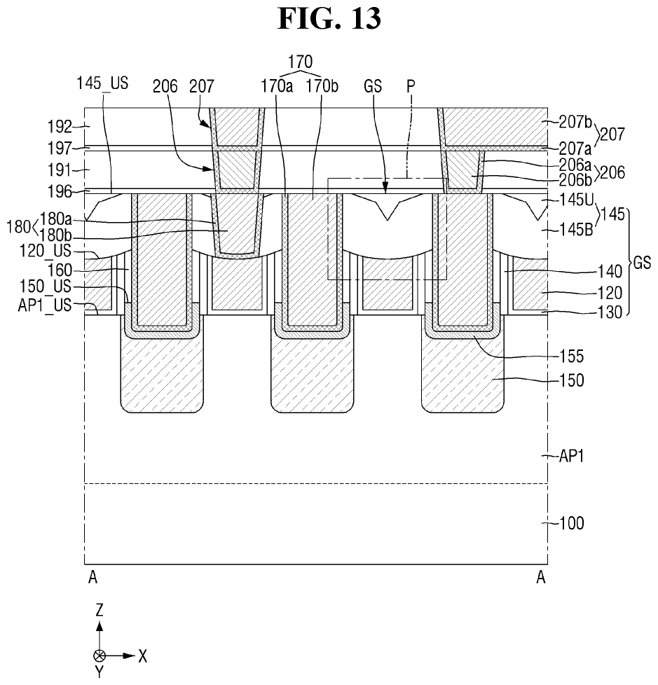

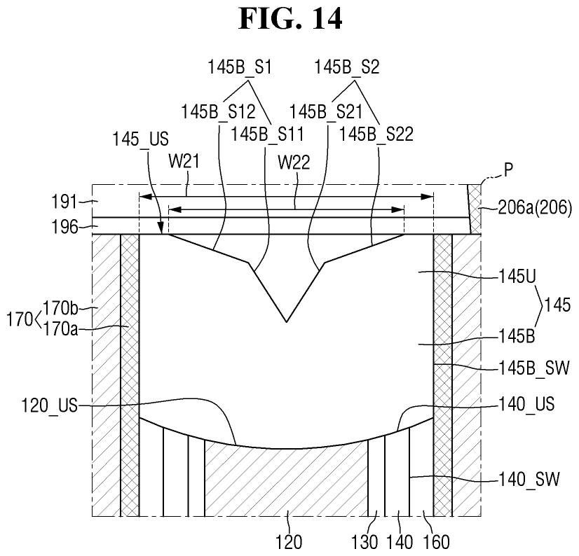

FIGS. 13 and 14 are example cross-sectional views of a semiconductor device according to some embodiments. For convenience of description, following descriptions mainly describe differences thereof from those as set forth with reference to FIGS. 1 to 5. For reference, FIG. 14 is an enlarged view of a P portion of FIG. 13.

Referring to FIGS. 13 and 14, in the semiconductor device according to some embodiments, the width W22 in the first direction X of the upper gate capping pattern 145U is smaller than the width W21 in the first direction X of the lower gate capping pattern 145B. The width W22 in the first direction X of the upper gate capping pattern 145U may be a widest width of the upper gate capping pattern 145U in the first direction X.

The upper surface 145_US of the gate capping pattern may include a portion defined by the upper gate capping pattern 145U and a portion defined by the lower gate capping pattern 145B.

The first source/drain contact 170 may contact the sidewall 145B_SW of the lower gate capping pattern. In the cross-sectional view as shown in FIG. 13, the first source/drain contact 170 may not contact the upper gate capping pattern 145U.

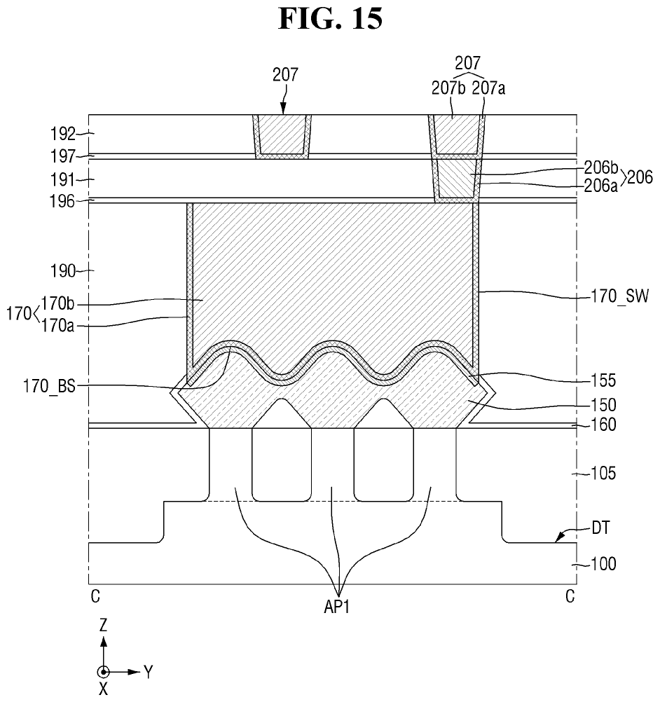

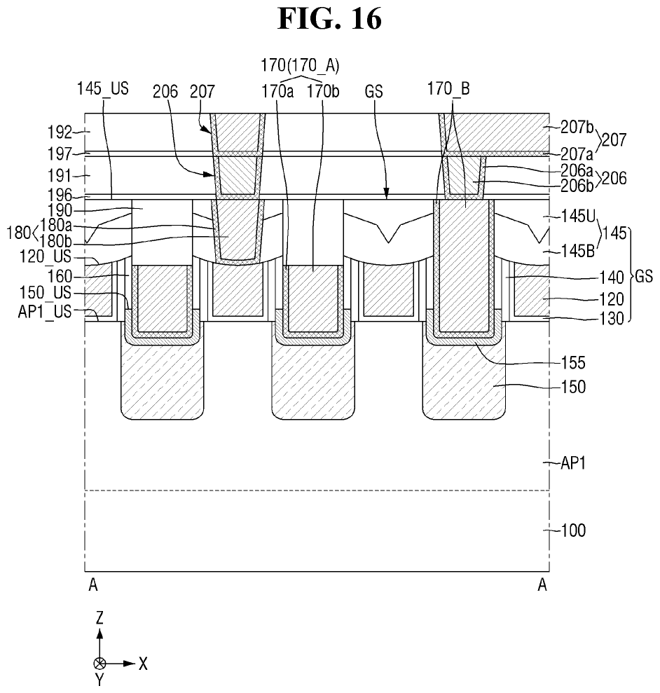

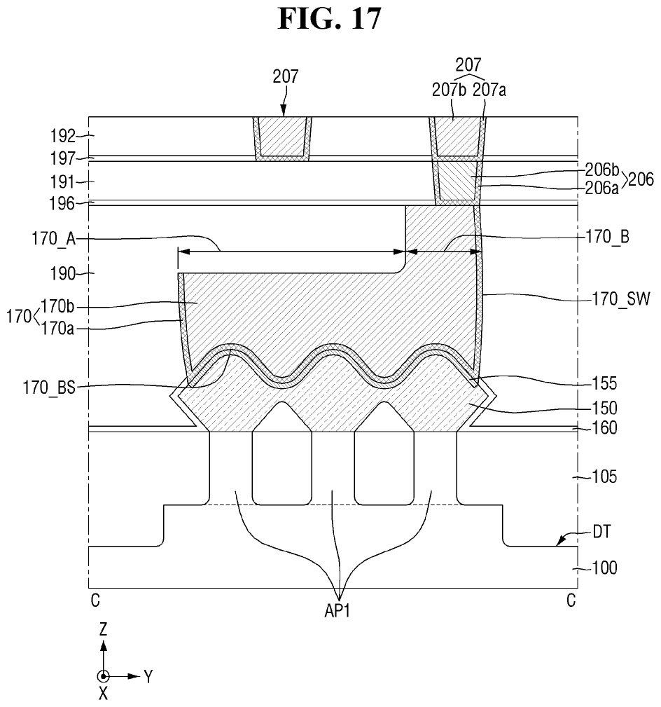

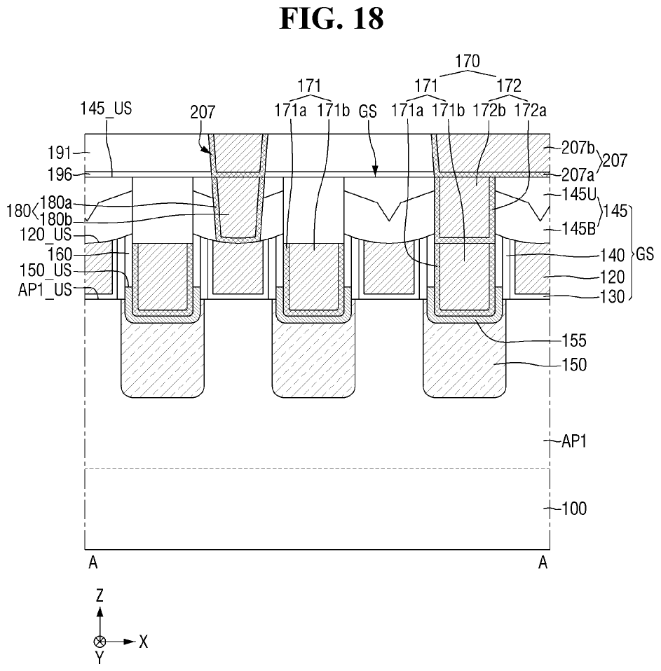

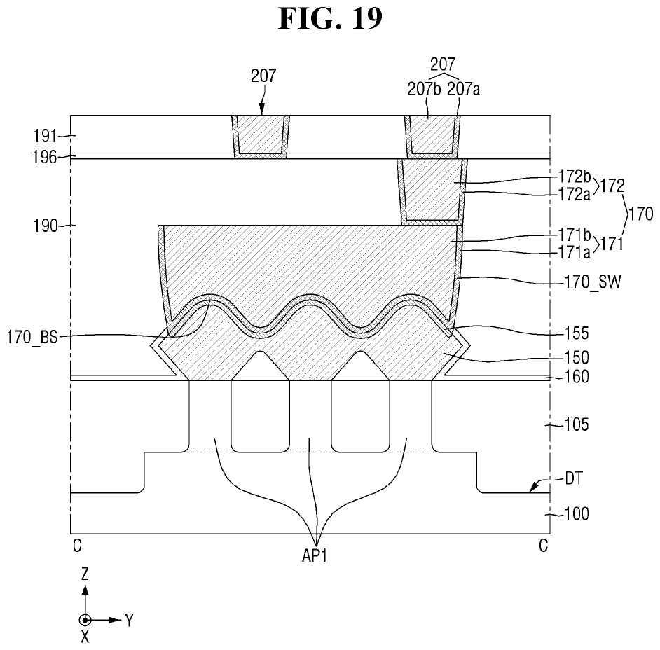

FIG. 15 is an example cross-sectional views of a semiconductor device according to some embodiments. FIGS. 16 and 17 are example cross-sectional views of a semiconductor device according to some embodiments. FIGS. 18 and 19 are example cross-sectional views of a semiconductor device according to some embodiments. For convenience of description, following descriptions mainly describe differences thereof from those as set forth with reference to FIGS. 1 to 5.

Referring to FIG. 15, in the semiconductor device according to some embodiments, the sidewall 170_SW of the first source/drain contact 170 may have a straight line shape in cross-sectional view.

Referring to FIGS. 16 and 17, in the semiconductor device according to some embodiments, the first source/drain contact 170 may include a first portion 170_A and a second portion 170_B.

The first portion 170_A of the first source/drain contact may be directly connected to the second portion 170_B of the first source/drain contact.

The second portion 170_B of the first source/drain contact refers to a portion onto which the via plug 206 is seated. The first source/drain contact 170 may be connected to the wiring line 207 via the second portion 170_B of the first source/drain contact. The via plug 206 is not seated on the first portion 170_A of the first source/drain contact 170.

For example, in the cross-sectional view as shown in FIG. 16, the second portion 170_B of the first source/drain contact 170 may be located at a position so as to be connected to the via plug 206. The first portion 170_A of the first source/drain contact may be located at a position so as not to be connected to the via plug 206.

Further, in order to prevent the gate contact 180 and the first source/drain contact 170 from being short-circuited with each other, the first portions 170_A of the first source/drain contacts may be located on both opposing sides of a portion of the gate structure GS connected to the gate contact 180, while the second portion 170_B of the first source/drain contact 170 may not be located on both opposing sides of the portion of the gate structure GS connected to the gate contact 180. That is, in the cross-sectional view as shown in FIG. 16, the first portions 170_A of the first source/drain contacts may be positioned on both opposing sides of the portion of the gate structure GS connected to the gate contact 180, while the second portion 170_B of the first source/drain contact may not be positioned on both opposing sides of the portion of the gate structure GS connected to the gate contact 180.

A height of an upper surface of the second portion 170_B of the first source/drain contact is higher than that of an upper surface of the first portion 170_A of the first source/drain contact. In FIG. 17, based on the upper surface of the field insulating film 105, a height of the upper surface of the second portion 170_B of the first source/drain contact may be bigger than a height of the first portion 170_A of the first source/drain contact. For example, the upper surface of the first source/drain contact 170 may be the upper surface of the second portion 170_B of the first source/drain contact.

In FIG. 17, the first source/drain contact 170 is illustrated as having an L-shape. However, the present disclosure is not limited thereto. Unlike what is illustrated, the first source/drain contact 170 may have a T-shape rotated 180 degrees (e.g., an inverted T-shape). In this case, the first portion 170_A of the first source/drain contact may be disposed on each of opposing sides of the second portion 170_B of the first source/drain contact.

The first interlayer insulating film 190 may not cover the upper surface of the second portion 170_B of the first source/drain contact. The first interlayer insulating film 190 may cover the upper surface of the first portion 170_A of the first source/drain contact.

Referring to FIGS. 18 and 19, in the semiconductor device according to some embodiments, the first source/drain contact 170 may include a lower source/drain contact 171 and an upper source/drain contact 172.

The lower source/drain contact 171 may include a lower source/drain barrier film 171a and a lower source/drain filling film 171b. The upper source/drain contact 172 may include an upper source/drain barrier film 172a and an upper source/drain filling film 172b.

The upper surface of the first source/drain contact 170 may be an upper surface of the upper source/drain contact 172.

A description directed to a material of each of the lower source/drain barrier film 171a and the upper source/drain barrier film 172a may be the same as the above description of the material of the source/drain barrier film 170a. A description directed to a material of each of the lower source/drain filling film 171b and the upper source/drain filling film 172b may be the same as the description directed to the material of the source/drain filling film 170b. Unlike what is illustrated, the upper source/drain contact 172 may be embodied as a single film.

The wiring line 207 may be connected to the first source/drain contact 170 and the gate contact 180 without the via plug (e.g., the via plug 206 in FIG. 2). The wiring line 207 may be disposed in the first etch stop film 196 and the second interlayer insulating film 191.

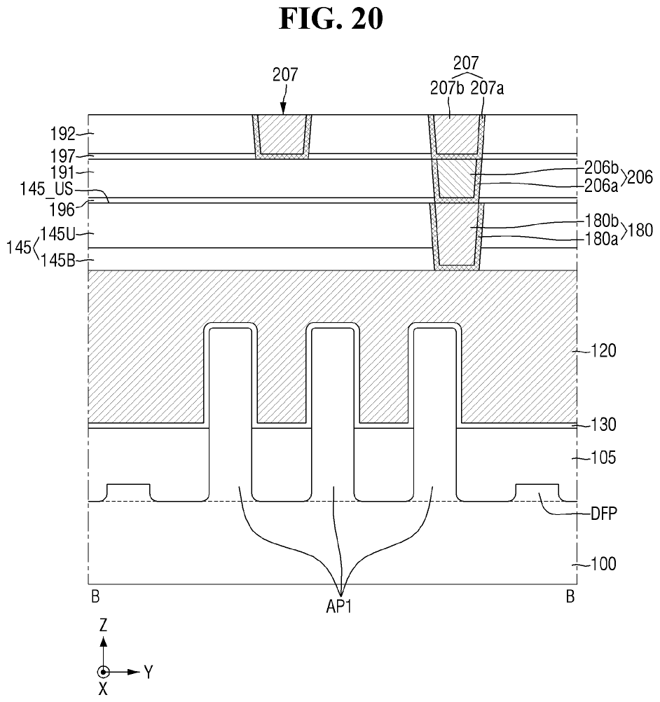

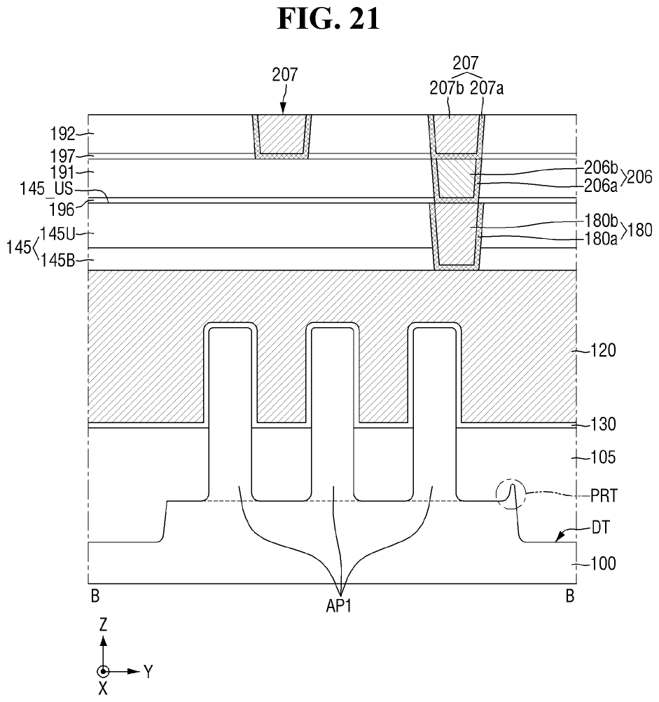

FIG. 20 is an example cross-sectional view of a semiconductor device according to some embodiments. FIG. 21 is an example cross-sectional view of a semiconductor device according to some embodiments. For convenience of description, following descriptions mainly describe differences thereof from those as set forth with reference to FIGS. 1 to 5.

Referring to FIG. 20, the semiconductor device according to some embodiments may include a dummy protruding pattern DFP formed in the field area FX.

The deep trench (e.g., the deep trench DT in FIG. 2) is not formed in the field area FX. An upper surface of the dummy protruding pattern DFP is covered with the field insulating film 105. The dummy protruding pattern DFP may include the same material as that of the first active pattern AP1.

Referring to FIG. 21, the semiconductor device according to some embodiments may further include a protruding structure PRT disposed along a boundary of the first active area RX1.

The protruding structure PRT may be disposed at the boundary of the first active area RX1 extending along the first direction X. A first sidewall of the protruding structure PRT may be defined by a fin trench defining the first active pattern AP1, and a second sidewall of the protruding structure PRT may be defined by the deep trench DT. The protruding structure PRT may extend in an elongated manner in the first direction X. Stated differently, the protruding structure PRT may extend longitudinally in the first direction X.

The protruding structure PRT is covered with the field insulating film 105. The protruding structure PRT may include the same semiconductor material as that of the first active pattern AP1.

The protruding structure PRT is illustrated as being disposed along one of two boundaries of the first active area RX1 extending along the first direction X. However, the present disclosure is not limited thereto. Unlike what is illustrated, in another example, the protruding structure PRT may be disposed along the two boundaries of the first active area RX1 extending along the first direction X.

Although not shown, the protruding structure PRT may be disposed at an edge of the second active area RX2.

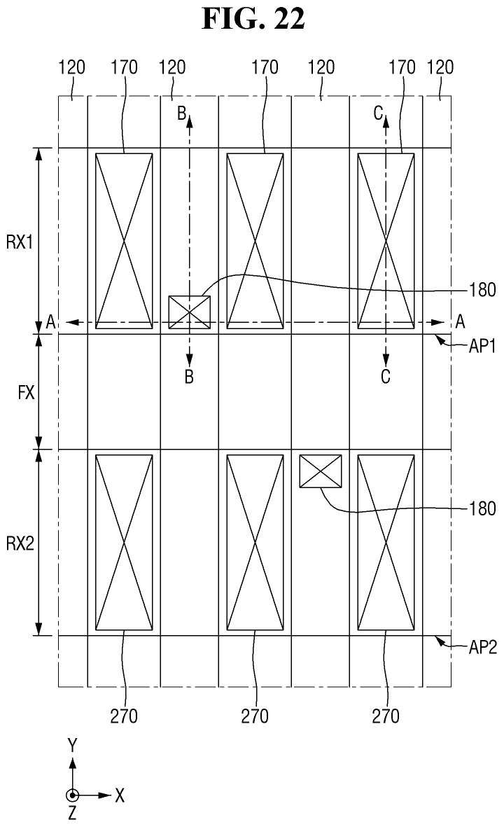

FIGS. 22 to 26 are diagrams for illustrating a semiconductor device according to some embodiments. For convenience of description, following descriptions mainly describe differences thereof from those as set forth with reference to FIGS. 1 to 5.

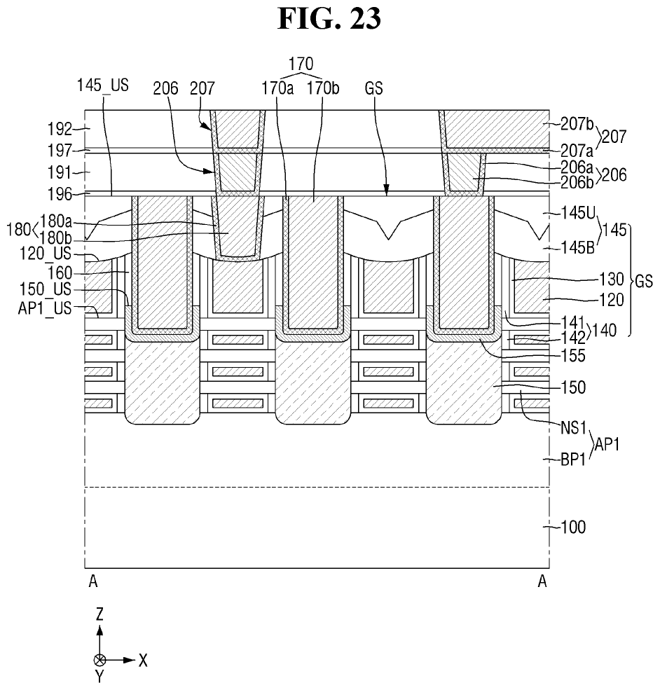

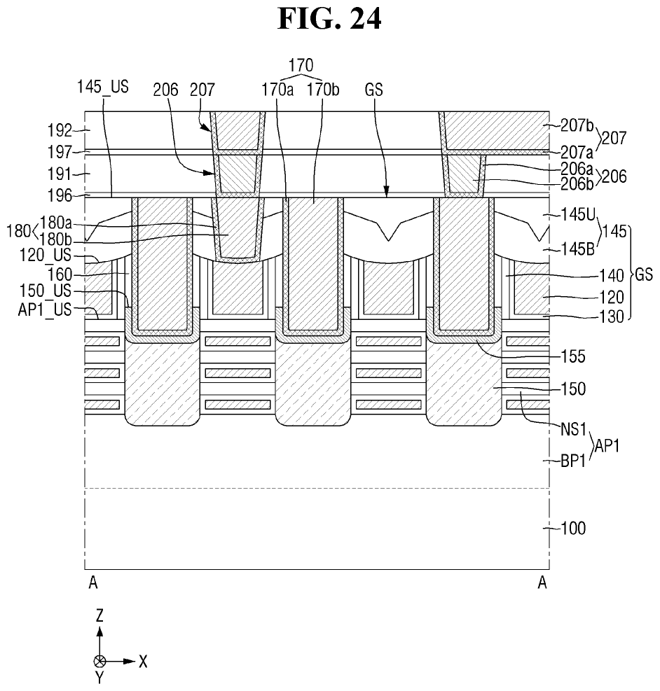

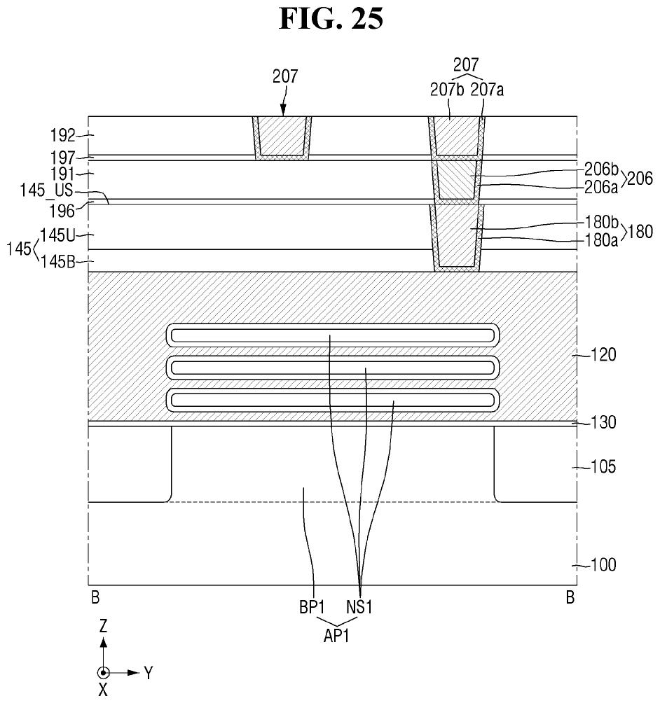

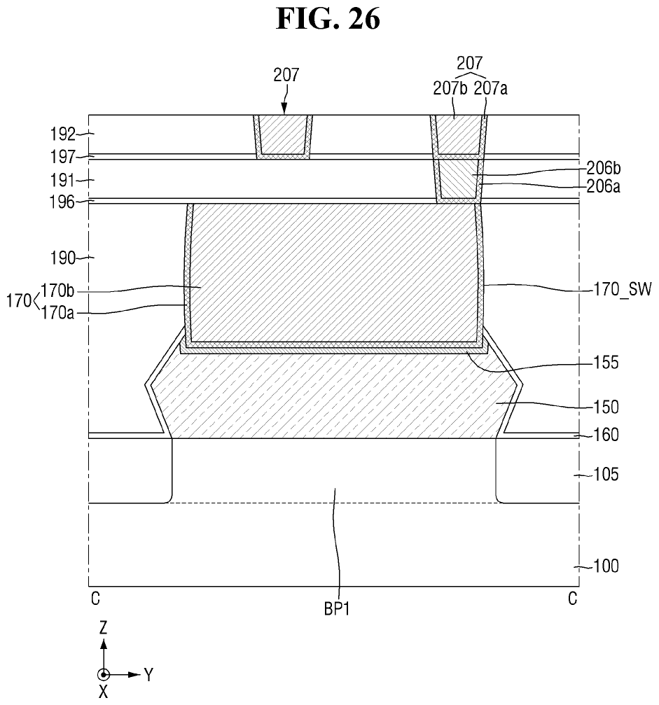

For reference, FIG. 22 is an example layout diagram of a semiconductor device according to some embodiments. FIGS. 23 and 24 are each example cross-sectional views taken along A-A of FIG. 22. FIG. 25 is a cross-sectional view taken along B-B of FIG. 22. FIG. 26 is a cross-sectional view taken along C-C of FIG. 22.

Referring to FIGS. 22 to 26, in the semiconductor device according to some embodiments, the first active pattern AP1 may include a bottom pattern BP1 and a sheet pattern NS1.

Although not shown, the second active pattern AP2 may include a bottom pattern and a sheet pattern.

The bottom pattern BP1 may extend along the first direction X. The sheet pattern NS1 may be disposed on the bottom pattern BP1 and spaced apart from the bottom pattern BP1.

The sheet pattern NS1 may include a plurality of sheet patterns stacked in the third direction Z. Although it is illustrated that the sheet pattern NS1 includes three sheet patterns, this is intended only for convenience of illustration, and the present disclosure is not limited thereto. An upper surface of an uppermost sheet pattern of the sheet patterns NS1 may be the upper surface AP1_US of the first active pattern.

The sheet pattern NS1 may be connected to the first source/drain pattern 150. The sheet pattern NS1 may be a channel pattern used as a channel area of a transistor. For example, the sheet pattern NS1 may be a nanosheet or a nanowire.

The bottom pattern BP1 may include, for example, silicon or germanium as an elemental semiconductor material. In some embodiments, the bottom pattern BP1 may include a compound semiconductor, for example, a group IV-IV compound semiconductor or a group III-V compound semiconductor.

The sheet pattern NS1 may include, for example, silicon or germanium which is an elemental semiconductor material. In some embodiments, the sheet pattern NS1 may include a compound semiconductor, for example, a group IV-IV compound semiconductor or a group III-V compound semiconductor.

The gate insulating film 130 may extend along an upper surface of the bottom pattern BP1 and the upper surface of the field insulating film 105. The gate insulating film 130 may surround the sheet pattern NS1.

The gate electrode 120 is disposed on the bottom pattern BP1. The gate electrode 120 intersects or traverses the bottom pattern BP1. The gate electrode 120 may surround the sheet pattern NS1. The gate electrode 120 may be disposed between the bottom pattern BP1 and the sheet pattern NS1 and between adjacent sheet patterns NS1.

In FIG. 23, the gate spacer 140 may include an outer spacer 141 and an inner spacer 142. The inner spacer 142 may be disposed between the bottom pattern BP1 and the sheet pattern NS1, and between adjacent sheet patterns NS1.

In FIG. 24, the gate spacer 140 may include only the outer spacer. The inner spacer is not disposed between the bottom pattern BP1 and the sheet pattern NS1, and between adjacent sheet patterns NS1.

A bottom surface of the first source/drain contact 170 may be positioned between an upper surface of the lowermost sheet pattern among the plurality of sheet patterns NS1 and a bottom surface of an uppermost sheet pattern among the plurality of sheet patterns NS1. Unlike what is illustrated, the bottom surface of the first source/drain contact 170 may be located between an upper surface of the sheet pattern NS1 disposed on uppermost and a bottom surface of the sheet pattern NS1 disposed on uppermost. In some embodiments, the bottom surface of the first source/drain contact 170 may be at a height between an upper surface and a lower surface of an uppermost sheet pattern of the plurality of sheet patterns NS1.

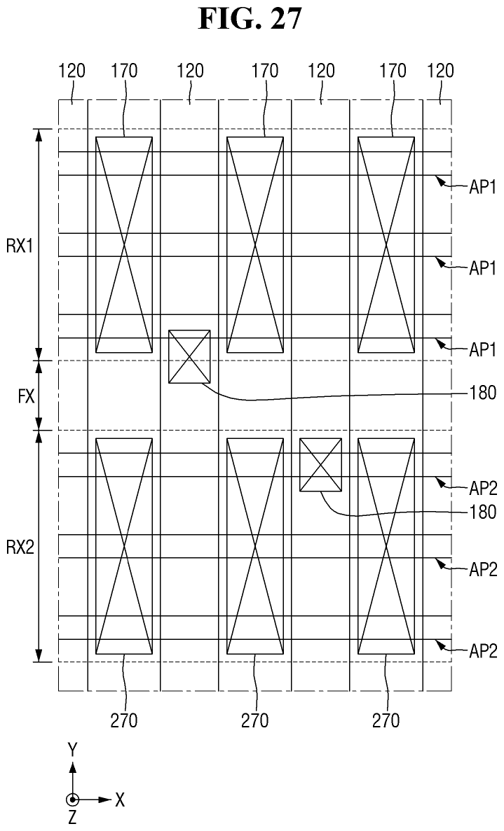

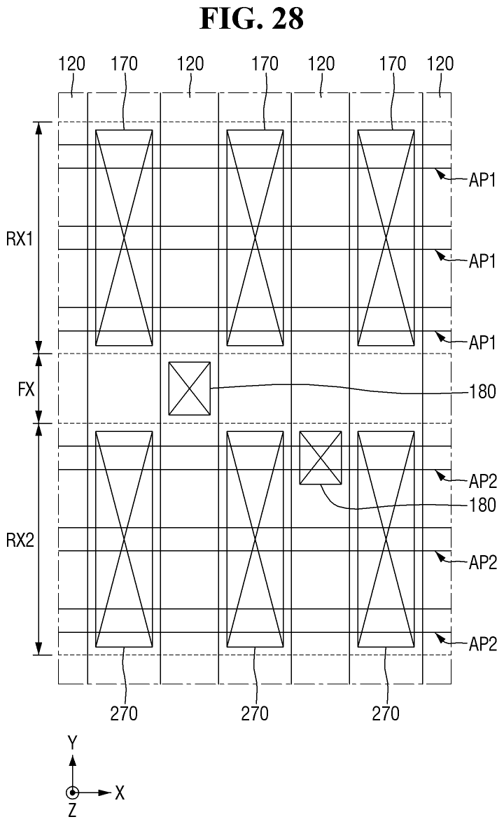

FIGS. 27 and 28 are example layout diagrams of a semiconductor device according to some embodiments, respectively. For convenience of description, following descriptions mainly describe differences thereof from those as set forth with reference to FIGS. 1 to 5.

Referring to FIG. 27, in the semiconductor device according to some embodiments, in a plan view, at least one of the gate contacts 180 may be disposed across the active area RX1 or RX2, and the field area FX.

For example, a portion of the gate contact 180 may be disposed at a position overlapping the first active area RX1.

Referring to FIG. 28, in the semiconductor device according to some embodiments, in a plan view, at least one of the gate contacts 180 may be entirely disposed on the field area FX.

At least one of the gate contacts 180 may overlap entirely with the field area FX.

In FIGS. 27 and 28, it is illustrated that at least one of the remaining ones of the gate contact 180 is entirely disposed on the second active area RX2. However, the present disclosure is not limited thereto.

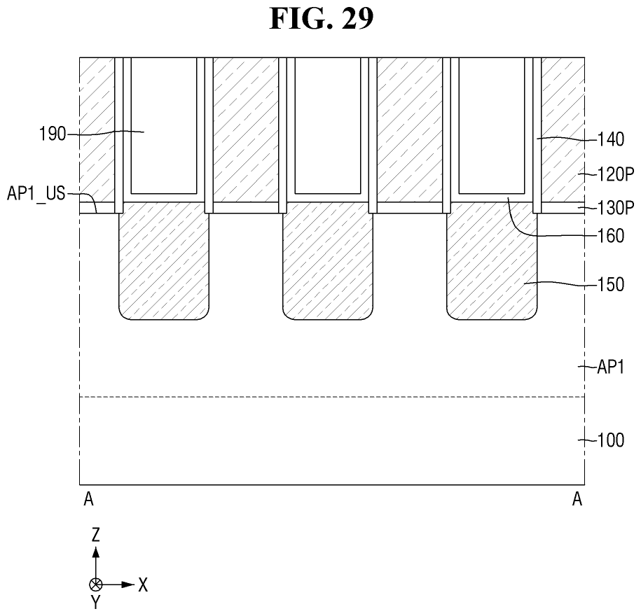

FIGS. 29 to 38 are example cross-sectional views of intermediate steps illustrating a semiconductor device manufacturing method according to some embodiments. For reference, FIGS. 29 to 38 may be cross-sectional views taken along A-A of FIG. 1. Hereinafter, the method for manufacturing the device is described based on those cross-sectional views.

Referring to FIG. 29, a dummy gate electrode 120P and a dummy gate insulating film 130P may be formed on the first active pattern AP1.

The gate spacer 140 may be formed on a sidewall of the dummy gate electrode 120P and a sidewall of the dummy gate insulating film 130P. The source/drain pattern 150 may be formed between adjacent dummy gate electrodes 120P. The source/drain pattern 150 may be formed on the first active pattern AP1.

The source/drain etch stop film 160 and the first interlayer insulating film 190 are sequentially formed on the source/drain pattern 150. After the first interlayer insulating film 190 has been formed, the dummy gate electrode 120P may be exposed.

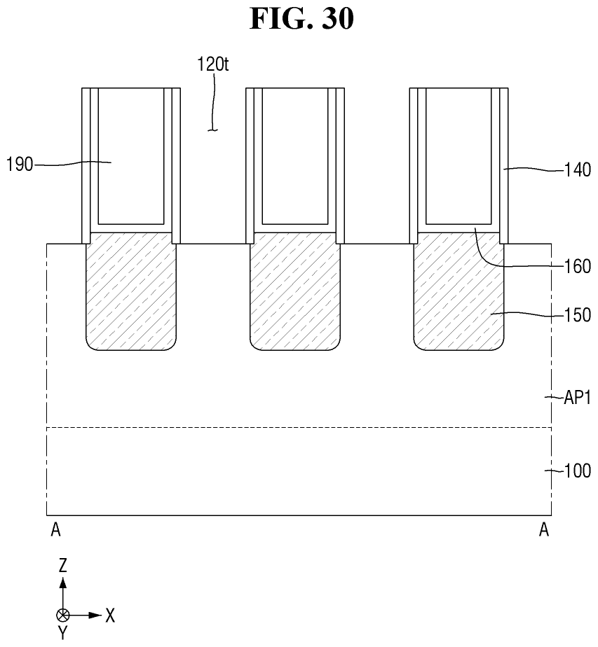

Referring to FIG. 30, a gate trench 120t may be formed by removing the dummy gate electrode 120P and the dummy gate insulating film 130P.

The gate trench 120t may expose the first active pattern AP1.

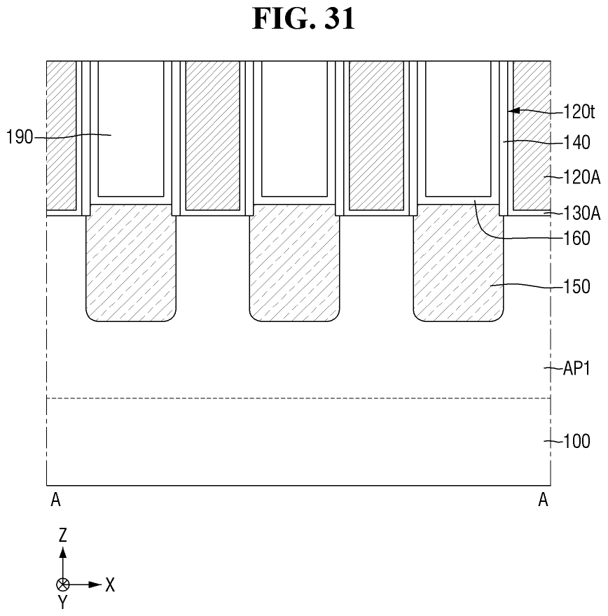

Referring to FIG. 31, a pre-gate insulating film 130A and a pre-gate electrode 120A may be formed on the first active pattern AP1.

The pre-gate insulating film 130A may extend along a sidewall and a bottom surface of the gate trench 120t. The pre-gate insulating film 130A may not be formed on an upper surface of the first interlayer insulating film 190A.

The pre-gate electrode 120A may be formed on the pre-gate insulating film 130A. The pre-gate electrode 120A may fill the gate trench 120t. The pre-gate electrode 120A may not be formed on the upper surface of the first interlayer insulating film 190.

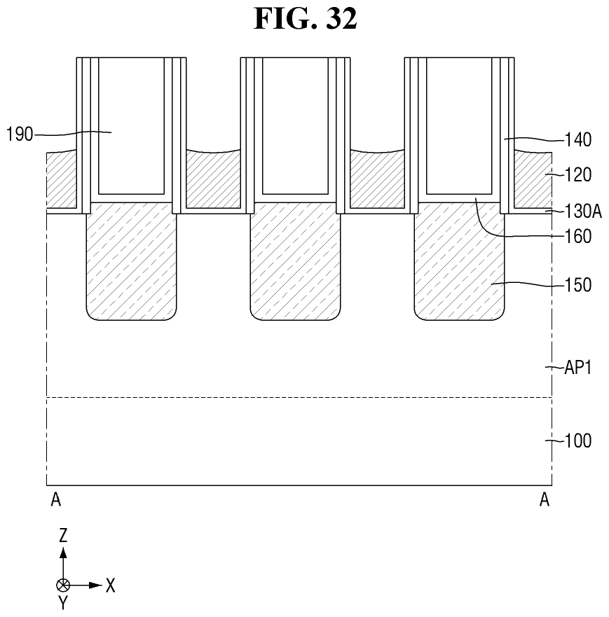

Referring to FIG. 32, the gate electrode 120 may be formed by removing a portion of the pre-gate electrode 120A.

The gate electrode 120 fills a portion of the gate trench 120t. The gate electrode 120 is formed on the pre-gate insulating film 130A.

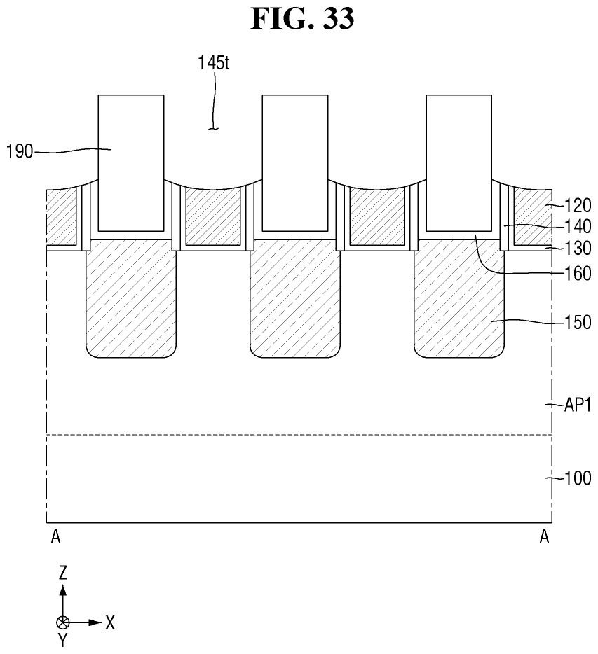

Referring to FIG. 33, a portion of the pre-gate insulating film 130A, a portion of the gate spacer 140, and a portion of the source/drain etch stop film 160 may be removed to form a gate capping trench 145t.

A portion of the pre-gate insulating film 130A may be removed to form the gate insulating film 130. A bottom surface of the gate capping trench 145t may be defined by the gate electrode 120, the gate insulating film 130, the gate spacer 140, and the source/drain etch stop film 160. A sidewall of the gate capping trench 145t may be defined by the first interlayer insulating film 190.

Unlike what is illustrated in FIGS. 32 and 33, while the portion of the pre-gate electrode 120A is removed, a portion of the pre-gate insulating film 130A may also be removed.

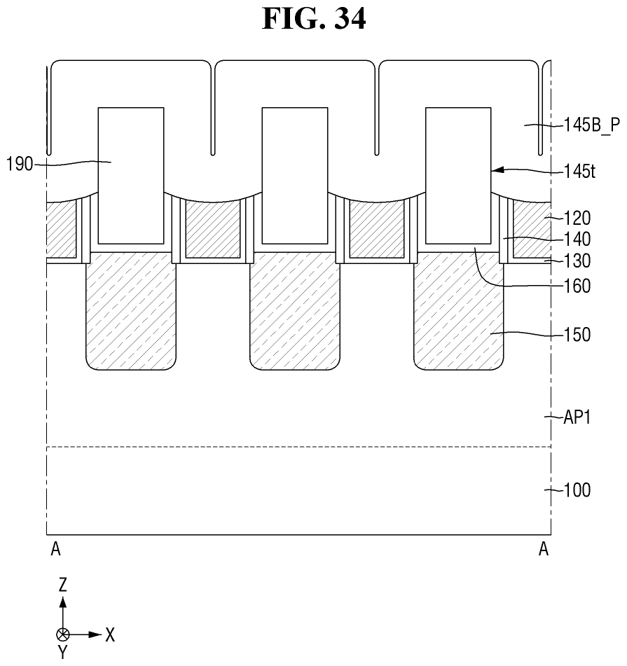

Referring to FIG. 34, the lower gate capping film 145B_P may be formed in the gate capping trench 145t.

The lower gate capping film 145B_P may fill the gate capping trench 145t. The lower gate capping film 145B_P may be formed on an upper surface of the first interlayer insulating film 190.

The lower gate capping film 145B_P formed in the gate capping trench 145t may include a seam pattern (also referred to as a seam) or a cavity (e.g., an air gap). However, the present disclosure is not limited thereto.

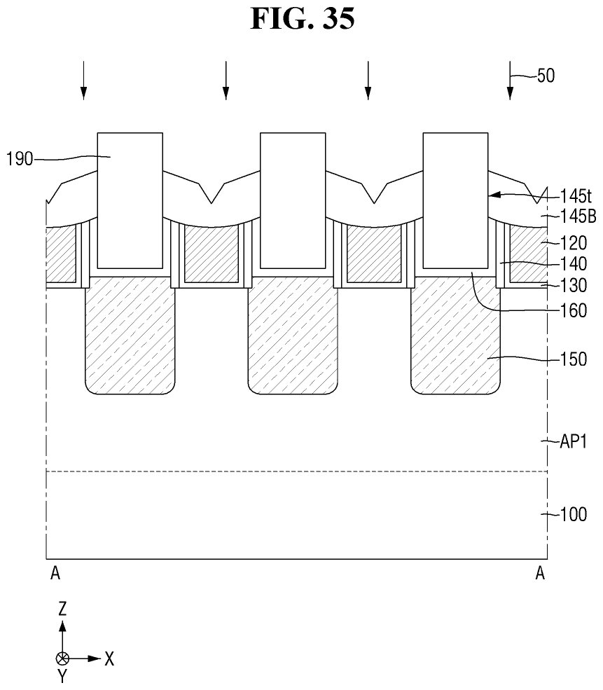

Referring to FIGS. 34 and 35, using an etching process 50, a portion of the lower gate capping film 145B_P may be removed.

Through this, the lower gate capping pattern 145B may be formed in the gate capping trench 145t. The lower gate capping pattern 145B fills a portion of the gate capping trench 145t. While the lower gate capping pattern 145B is being formed, a portion of the lower gate capping film 145B_P on the upper surface of the first interlayer insulating film 190 may be removed.

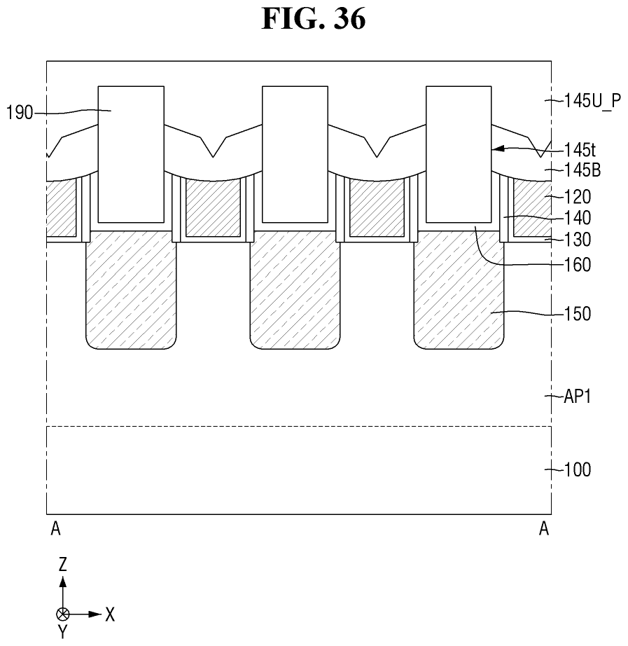

Referring to FIG. 36, the upper gate capping film 145U_P may be formed on the lower gate capping pattern 145B.

The upper gate capping film 145U_P may fill the remainder of the gate capping trench 145t. The upper gate capping film 145U_P may be formed on the upper surface of the first interlayer insulating film 190.

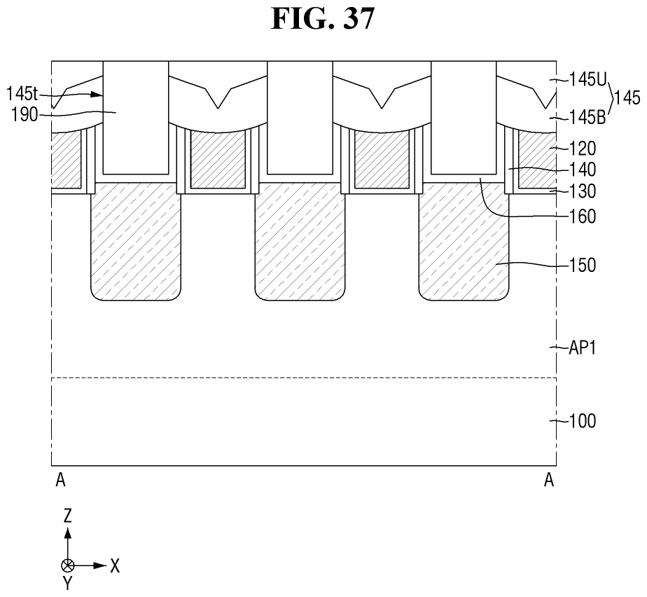

Referring to FIGS. 36 and 37, a portion of the upper gate capping film 145U_P may be removed by a planarization process.

Through this, the upper gate capping pattern 145U may be formed in the gate capping trench 145t. The upper gate capping pattern 145U is formed on the lower gate capping pattern 145B. The gate capping pattern 145 may fill the gate capping trench 145t.

While the upper gate capping pattern 145U is being formed, a portion of the upper gate capping film 145U_P on the upper surface of the first interlayer insulating film 190 may be removed. Further, while the upper gate capping pattern 145U is being formed, a portion of the first interlayer insulating film 190 may be removed.

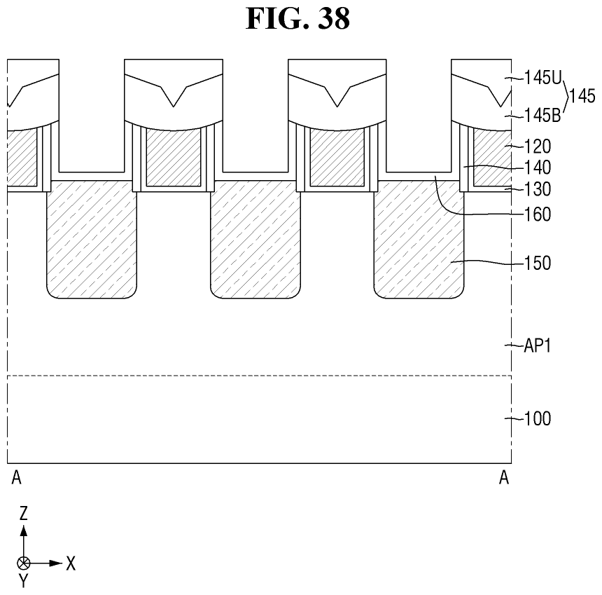

Referring to FIG. 38, the source/drain etch stop film 160 may be exposed by removing the first interlayer insulating film 190.

Referring back to FIG. 2, the source/drain pattern 150 may be exposed by removing a portion of the source/drain etch stop film 160.

The first source/drain contact connected to the source/drain pattern 150 may be formed on the exposed source/drain pattern 150.

In concluding the detailed description, those skilled in the art will appreciate that many variations and modifications may be made to the embodiments described herein without substantially departing from the principles of the present inventive concept. Therefore, the disclosed embodiments of the invention are used in a generic and descriptive sense only and not for purposes of limitation.

What is claimed is:

1. A semiconductor device comprising:
an active pattern extending in a first direction;
a gate structure including a gate electrode, a gate spacer, and a gate capping pattern on the active pattern, the gate electrode extending in a second direction different from the first direction and the gate capping pattern including a lower gate capping pattern and an upper gate capping pattern on the lower gate capping pattern;
a source/drain pattern on the active pattern; and
a source/drain etch stop film on an upper surface of the source/drain pattern and extending along a sidewall of the gate spacer,
wherein the lower gate capping pattern is on an upper surface of the gate electrode and an upper surface of the gate spacer, and
a sidewall of the lower gate capping pattern is free of the source/drain etch stop film.

2. The semiconductor device of claim 1, wherein an upper surface of the lower gate capping pattern includes a first inclined surface and a second inclined surface connected to each other, and
a distance, in the first direction, between the first inclined surface and the second inclined surface increases as a distance from the upper surface of the gate electrode increases.

3. The semiconductor device of claim 1, wherein the gate capping pattern further includes a cavity or a seam between the upper gate capping pattern and the lower gate capping pattern.

4. The semiconductor device of claim 1, wherein the upper gate capping pattern further includes a cavity or a seam.

5. The semiconductor device of claim 1, further comprising a source/drain contact that is on and connected to the source/drain pattern,
wherein the source/drain contact is in contact with the source/drain etch stop film, the lower gate capping pattern and the upper gate capping pattern.

6. The semiconductor device of claim 1, wherein the gate capping pattern further includes an inserted gate capping pattern that is between the upper gate capping pattern and the lower gate capping pattern, and
a width of the upper gate capping pattern in the first direction is wider than a width of the inserted gate capping pattern in the first direction.

7. The semiconductor device of claim 1, wherein a width of the upper gate capping pattern in the first direction is equal to or smaller than a width of the lower gate capping pattern in the first direction.

8. The semiconductor device of claim 1, wherein the upper gate capping pattern includes an upper surface of the gate capping pattern.

9. The semiconductor device of claim 1, wherein the active pattern includes a bottom pattern extending in the first direction, and a plurality of sheet patterns spaced apart from the bottom pattern in a third direction.

10. A semiconductor device comprising:
an active pattern extended in a first direction;
a gate structure including a gate electrode, a gate spacer, and a gate capping pattern on the active pattern, the gate electrode extending in a second direction different from the first direction, the gate capping pattern including a lower gate capping pattern and an upper gate capping pattern on the lower gate capping pattern;
a source/drain pattern on the active pattern; and
a source/drain etch stop film on an upper surface of the source/drain pattern and extending along a sidewall of the gate spacer,
wherein the lower gate capping pattern is in contact with an upper surface of the gate electrode and an upper surface of the gate spacer,
an upper surface of the lower gate capping pattern includes a first inclined surface and a second inclined surface connected to each other, and
the first inclined surface of the upper surface of the lower gate capping pattern and the second inclined surface of the upper surface of the lower gate capping pattern are in contact with the upper gate capping pattern.

11. The semiconductor device of claim 10, wherein the first inclined surface and the second inclined surface diverge in a direction away from the upper surface of the gate electrode.

12. The semiconductor device of claim 10, wherein an upper surface of the gate capping pattern is free of the source/drain etch stop film.

13. The semiconductor device of claim 10, wherein a width of the upper gate capping pattern in the first direction is equal to a width of the lower gate capping pattern in the first direction.

14. The semiconductor device of claim 10, wherein the upper gate capping pattern further includes a cavity or a seam.

15. The semiconductor device of claim 10, wherein the gate capping pattern further includes a cavity or a seam that is between the upper gate capping pattern and the lower gate capping pattern.

16. A semiconductor device comprising:
an active pattern which includes a bottom pattern extending in a first direction and a plurality of sheet patterns space apart from the bottom pattern in a second direction;
a gate structure including a gate electrode, a gate spacer, and a gate capping pattern on the active pattern, the gate electrode extending in a third direction, the gate capping pattern including a lower gate capping pattern and an upper gate capping pattern on the lower gate capping pattern;
a source/drain pattern on the active pattern; and
a source/drain etch stop film on an upper surface of the source/drain pattern and extending along a sidewall of the gate spacer,
wherein the lower gate capping pattern is in contact with an upper surface of the gate electrode and an upper surface of the gate spacer,
the upper gate capping pattern includes a first cavity or a first seam, and
the upper gate capping pattern defines an upper surface of the gate capping pattern.

17. The semiconductor device of claim 16, wherein the upper surface of the gate capping pattern is free of the source/drain etch stop film.

18. The semiconductor device of claim 16, wherein the gate capping pattern further includes a second cavity or a second seam that is between the upper gate capping pattern and the lower gate capping pattern.

19. The semiconductor device of claim 16, wherein an upper surface of the lower gate capping pattern includes a first inclined surface and a second inclined surface connected to each other, and
the first inclined surface of the upper surface of the lower gate capping pattern and the second inclined surface of the upper surface of the lower gate capping pattern are in contact with the upper gate capping pattern.

20. The semiconductor device of claim 19, wherein the first inclined surface and the second inclined surface diverge in a direction away from the upper surface of the gate electrode.
